(19) United States
(12) Patent Application Publication
(10) Pub. No.: US 2023/0127519 A1
(43) Pub. Date: Apr. 27, 2023

(54) Articles Including Nanostructured Surfaces and Enclosed Voids

(71) Applicant: 3M INNOVATIVE PROPERTIES COMPANY, St. Paul, MN (US)

(72) Inventors: Jeffrey L. Solomon, Centerville, MN (US); Stephen M. Menke, Eagan, MN (US); Nicholas C. Erickson, St. Paul, MN (US); Daniel W. Hennen, Cottage Grove, MN (US); Derek W. Patzman, Prior Lake, MN (US); Thomas P. Klun, Lakeland, MN (US)

(21) Appl. No.: 17/915,534

(22) PCT Filed: Apr. 13, 2021
(86) PCT No.: PCT/IB2021/053049

§ 371 Date: Sep. 29, 2022

Related U.S. Application Data
(60) Provisional application No. 63/016,477, filed on Apr. 28, 2020.
(60) Provisional application No. 63/152,934, filed on Feb. 24, 2021.

(51) Int. Cl. G02B 1/14; H10K 50/858

(52) U.S. Cl. CPC G02B 1/14; H01L 51/5275; G02B 2207/101

(57) ABSTRACT

The present disclosure provides an article including either at least two layers each having at least one enclosed void that is defined in part by nanostructured surfaces, or a layer having at least one enclosed void that is defined by two nanostructured surfaces in contact with each other. In addition, the present disclosure provides an optical information display and an OLED device including the article. The nanostructured surface of the article is protected from damage and contamination by the presence of another layer.

### TECHNICAL FIELD

The present disclosure broadly relates to articles including nanostructured surfaces and methods of making such articles.

### BACKGROUND

Nanostructured surfaces can provide optical effects useful for a variety of applications such as improving the color and efficiency of devices (e.g., OLED displays). A refractive index difference or contrast is required at the nanostructured interface for the nanostructured surface to provide the desired optical functionality. The nanostructured surface can be exposed to the ambient environment to provide the refractive index contrast; however, the exposed surface limits attachment of the nanostructured surface to other surfaces and is susceptible to damage and/or contamination from the environment. Thus, there remains a need for improvements in protecting nanostructured surfaces.

### SUMMARY

In a first aspect, an article is provided. The article includes a) a first layer including a nanostructured first surface having nanofeatures and an opposing second surface. The nanostructured first surface has recessed features, or protruding features formed of a single composition, or both recessed and protruding features; and either b1) or b2). b1) is a second layer including a first major surface and an opposing second major surface, the first major surface attached to a portion of the nanofeatures of the first layer. The nanostructured first surface of the first layer and the first major surface of the second layer together define at least one first void. b2) is a third layer including a nanostructured first surface having nanofeatures and an opposing second surface, wherein a portion of the nanofeatures of the third layer are attached to a portion of the nanofeatures of the first layer. The nanostructured first surface of the third layer and the nanostructured first surface of the first layer together define at least one second void. The article includes the proviso that when b1) is present, the article further includes c) a fourth layer including a nanostructured first surface having nanofeatures and an opposing second surface. Either the second surface of the fourth layer or the nanostructured first surface of the fourth layer is adjacent either to the second major surface of the second layer or to the second surface of the first layer.

In a second aspect, an optical information display is provided including the article according to the first aspect.

In a third aspect, an OLED device is provided including the article according to the first aspect.

Articles according to at least certain embodiments of the present disclosure provide an enclosure of a nanostructured surface, which protects the nanostructured surface and maintains the refractive index contrast of the air interface, and different optical effects than enclosed void(s) provided by a single surface that is nanostructured.

The above summary of the present disclosure is not intended to describe each disclosed embodiment or every implementation of the present disclosure. The description that follows more particularly exemplifies illustrative embodiments. In several places throughout the application, guidance is provided through lists of examples, which examples can be used in various combinations. In each instance, the recited list serves only as a representative group and should not be interpreted as an exclusive list.

### BRIEF DESCRIPTION OF THE DRAWINGS

FIG. 1 is a schematic cross-sectional view of an exemplary article according to the present application.

FIG. 2 is a schematic cross-sectional view of another exemplary article according to the present application.

FIG. 3A is a schematic diagram of a cross-section of further exemplary article according to the present application.

FIG. 3B is a schematic diagram of a cross-section of an OLED construction according to Examples 1-4 and Comparative Examples 1-2 of the present application.

FIG. 4A is a schematic cross-sectional view of the exemplary article of Example 1, according to the present application.

FIG. 4B is a scanning electron microscopy (SEM) image of a cross-section of the exemplary article of Example 1, according to the present application.

FIG. 5A is a schematic cross-sectional view of the exemplary article of Example 2, according to the present application.

FIG. 5B is an SEM image of a cross-section of the exemplary article of Example 2, according to the present application.

FIG. 5C is an SEM image of a cross-section of an upper portion of the exemplary article of Example 2, according to the present application.

FIG. 5D is an SEM image of a cross-section of a lower portion of the exemplary article of Example 2, according to the present application.

FIG. 6A is a schematic cross-sectional view of the exemplary article of Example 3, according to the present application.

FIG. 6B is an SEM image of a cross-section of the exemplary article of Example 3, according to the present application.

FIG. 6C is an SEM image of a cross-section of an upper portion of the exemplary article of Example 3, according to the present application.

FIG. 6D is an SEM image of a cross-section of a lower portion of the exemplary article of Example 3, according to the present application.

FIG. 7A is a schematic cross-sectional view of the exemplary article of Example 4, according to the present application.

FIG. 7B is an SEM image of a cross-section of the exemplary article of Example 4, according to the present application.

FIG. 7C is an SEM image of a cross-section of an upper portion of the exemplary article of Example 4, according to the present application.

FIG. 7D is an SEM image of a cross-section of a lower portion of the exemplary article of Example 4, according to the present application.

FIG. 8 is an SEM image of a top view of a nanostructured surface of Film A, prepared according to the present application.

FIG. 9A is an SEM image of a top view of a nanostructured surface, preparable according to the present application.

FIG. 9B is an SEM image of a top view of a nanostructured surface of Film D, prepared according to the present application.

FIG. 10A is an SEM image of a perspective view of a nanostructured surface, preparable according to the present application.

FIG. 10B is an SEM image of a perspective view of a nanostructured surface of Film E, prepared according to the present application.

FIG. 11A a schematic diagram of a top view of yet another exemplary article according to the present application.

FIG. 11B is an SEM image of a cross-section of a portion of the exemplary article of Example 6, according to the present application.

FIG. 12A is an SEM image of a top view of a portion of the nanostructured first layer including recessed nanofeatures of Structured Sample B, according to the present application.

FIG. 12B is an SEM image of a cross-section of a portion of the exemplary article of Example 7, according to the present application.

While the above-identified figures set forth several embodiments of the disclosure, other embodiments are also contemplated, as noted in the description. The figures are not necessarily drawn to scale. In all cases, this disclosure presents the invention by way of representation and not limitation. It should be understood that numerous other modifications and embodiments can be devised by those skilled in the art, which fall within the scope and spirit of the principles of the invention.

### DETAILED DESCRIPTION OF ILLUSTRATIVE EMBODIMENTS

### Glossary

The term “adjacent” as used herein refers to a material or a layer that can either be in contact with another material or layer (i.e., directly adjacent), or separated from another material or layer by an intermediary material, layer, or gap.

The term “colorant” as used herein refers to a component that imparts color, including for instance, a pigment, a dye, and combinations thereof. The term “pigment” as used herein refers to a material loaded above its solubility resulting in non-dissolved (or non-dissolvable) particles.

The phrase “in planar contact” or “planarly contacting” is used to indicate that one layer or layered structure is contacting (and disposed either above or below) another layer or layered structure. Such contact is facial contact, rather than edge contact.

The term “organic layer” as used herein refers to a layer that comprises a majority (e.g., greater than 50 weight percent) of one or more materials including hydrocarbon compounds or their halogenated analogues, a three-dimensionally continuous polymeric matrix, or both.

The term “inorganic layer” as used herein refers to a layer that comprises a majority (e.g., greater than 50 weight percent) of one or more materials lacking compounds having carbon-hydrogen bonds or their halogenated analogues.

As used herein, “nanostructured” refers to a surface that includes topography in the form of nanofeatures, wherein the nanofeatures comprise material that define the surface, and wherein at least one of the height of nanofeatures or the width of nanofeatures is less than about a micron (i.e., a micrometer, or 1000 nanometers).

As used herein, “index of refraction” refers to a refractive index of a material in the plane of the material with respect to light at 633 nm and normal incidence, unless otherwise indicated.

As used herein, “gas” refers to any material is the gaseous phase at standard temperature and pressure (i.e., 0 degrees Celsius and 10⁵ pascals).

As used herein. “birefringent” means that the indices of refraction in orthogonal x, y, and z directions are not all the same. Index of refraction is designated as nₓ, n_{y}, and n_{z} for x, y, and z directions, respectively. For the layers described herein, the axes are selected so that x and y axes are in the plane of the layer and the z axis is normal to the plane of the layer and typically corresponds to the thickness or height of the layer. Where a refractive index in one in-plane direction is larger than a refractive index in another in-plane direction, the x-axis is generally chosen to be the in-plane direction with the largest index of refraction.

As used herein, “transparent to visible light” refers to the level of transmission of the unpatterned substrate or of the article being 60 percent or more, 70 percent or more, 80 percent or more, 90 percent or more, 95 percent or more, or 98 percent or more transmissive to at least one polarization state of visible light, where the percent transmission is normalized to the intensity of the incident, optionally polarized light. The term “visible” in connection with “transparent to visible light” is modifying the term “light,” so as to specify the wavelength range of light for which the article is transparent.

The words “preferred” and “preferably” refer to embodiments of the disclosure that may afford certain benefits, under certain circumstances. However, other embodiments may also be preferred, under the same or other circumstances. Furthermore, the recitation of one or more preferred embodiments does not imply that other embodiments are not useful, and is not intended to exclude other embodiments from the scope of the disclosure.

In this application, terms such as “a”, “an”, and “the” are not intended to refer to only a singular entity, but include the general class of which a specific example may be used for illustration. The terms “a”, “an”, and “the” are used interchangeably with the term “at least one.” The phrases “at least one of” and “comprises at least one of” followed by a list refers to any one of the items in the list and any combination of two or more items in the list.

As used herein, the term “or” is generally employed in its usual sense including “and/or” unless the content clearly dictates otherwise.

The term “and/or” means one or all of the listed elements or a combination of any two or more of the listed elements.

Also herein, all numbers are assumed to be modified by the term “about” and preferably by the term “exactly.” As used herein in connection with a measured quantity, the term “about” refers to that variation in the measured quantity as would be expected by the skilled artisan making the measurement and exercising a level of care commensurate with the objective of the measurement and the precision of the measuring equipment used. Also herein, the recitations of numerical ranges by endpoints include all numbers subsumed within that range as well as the endpoints (e.g., 1 to 5 includes 1, 1.5, 2, 2.75, 3, 3.80, 4, 5, etc.).

As used herein as a modifier to a property or attribute, the term “generally”, unless otherwise specifically defined, means that the property or attribute would be readily recognizable by a person of ordinary skill but without requiring absolute precision or a perfect match (e.g., within +/−20% for quantifiable properties). The term “substantially”, unless otherwise specifically defined, means to a high degree of approximation (e.g., within +/−10% for quantifiable properties) but again without requiring absolute precision or a perfect match. Terms such as same, equal, uniform, constant, strictly, and the like, are understood to be within the usual tolerances or measuring error applicable to the particular circumstance rather than requiring absolute precision or a perfect match.

As used herein, referring to features as “first”, “second”, “third”, and so on is solely for clarity to distinguish which feature is being described in a particular embodiment. The order of features may vary between different embodiments; for instance, the “second layer” in one embodiment may instead be referred to as the “third layer” in a different embodiment in which a different structure and/or material is described as a second layer.

### Articles

In a first aspect, an article is provided. The article comprises:

a) a first layer comprising a nanostructured first surface comprising nanofeatures and an opposing second surface, wherein the nanostructured first surface comprises recessed features, or protruding features formed of a single composition, or both recessed and protruding features; and either:

b1) a second layer comprising a first major surface and an opposing second major surface, the first major surface attached to a portion of the nanofeatures of the first layer, wherein the nanostructured first surface of the first layer and the first major surface of the second layer together define at least one first void; or

b2) a third layer comprising a nanostructured first surface comprising nanofeatures and an opposing second surface, wherein a portion of the nanofeatures of the third layer are attached to a portion of the nanofeatures of the first layer, and wherein the nanostructured first surface of the third layer and the nanostructured first surface of the first layer together define at least one second void;

with the proviso that when b1) is present, the article further comprises:

c) a fourth layer comprising a nanostructured first surface comprising nanofeatures and an opposing second surface,

wherein either the second surface of the fourth layer or the nanostructured first surface of the fourth layer is adjacent either to the second major surface of the second layer or to the second surface of the first layer.

It has been discovered that it is possible to form each of 1) an article containing at least two layers each comprising one or more voids defined by a nanostructured surface in contact with a substantially planar surface (sometimes referred to as single layer encapsulation); and 2) an article comprising one or more voids defined by two nanostructured surfaces in contact with each other (sometimes referred to as dual layer encapsulation). Articles including combinations of the features of 1) and 2) are also provided. The articles exhibit a refractive index difference, in which the nanostructured surface is protected from damage or contamination. Moreover, the articles provide different optical properties than ones including a single layer comprising one or more voids defined by one nanostructured surface and a substantially planar surface.

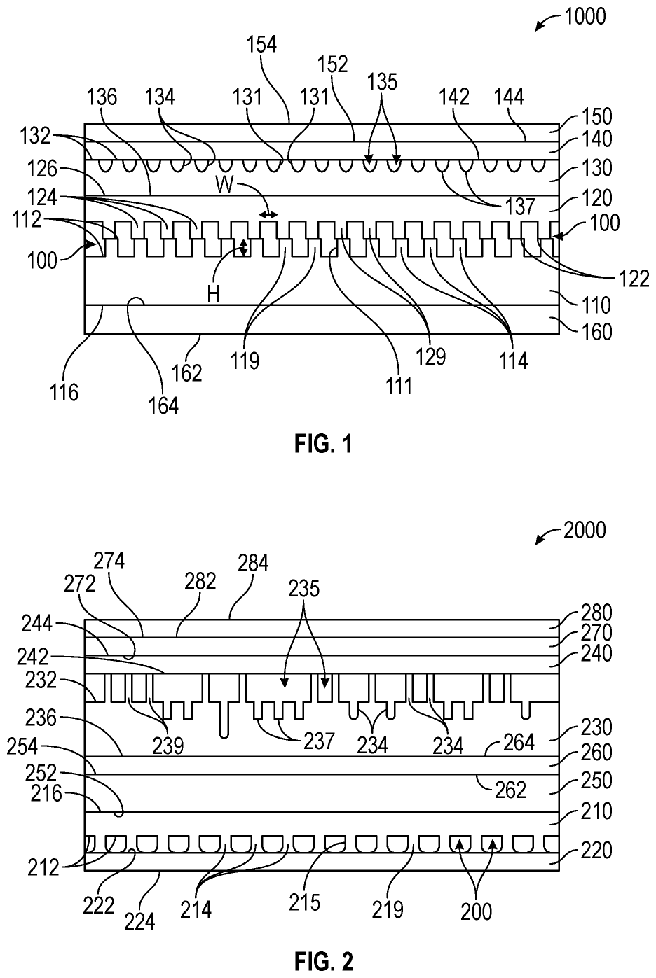

FIG. 1 is a schematic cross-sectional view of an exemplary article 1000, preparable according to the present application. The article 1000 comprises a first layer 110 comprising a nanostructured first surface 112 comprising nanofeatures 114 and an opposing second surface 116 and a second layer 120 comprising a nanostructured first surface 122 comprising nanofeatures 124 and an opposing second surface 126. A portion of the nanofeatures 124 of the second layer 120 are attached to a portion of the nanofeatures 114 of the first layer 110. Optionally, all of the nanofeatures of one layer are attached to portion of the nanofeatures of another layer, or all of the nanofeatures of both layers are attached to each other. The nanostructured first surface 122 of the second layer 120 and the nanostructured first surface 112 of the first layer 110 together define at least one first void 100 (e.g., in the form of the negative space between the first layer 110 and the second layer 120). The void(s) 100 are not filled with a solid or liquid, but rather contain a vacuum or a gas. Suitable gases include for example ambient air (e.g., atmospheric air in its natural state), a gas, or a gas blend (e.g., 90% nitrogen and 10% oxygen). In some embodiments, suitable gases can include at least one inert gas (e.g., nitrogen, argon, helium, xenon, etc.).

In the embodiment shown in FIG. 1, each of the nanostructured first surface 112 of the first layer 110 and the nanostructured first surface 122 of the second layer 120 comprise protruding features 119 and 129, respectively. In any article according to the present disclosure, the nanostructured first surface optionally comprises recessed features, or protruding features formed of a single composition, or both recessed and protruding features. By a “single composition” is meant that the protruding features are made of the same material throughout the protruding feature instead of including one portion of a feature having a differing composition than another portion of the same feature. In some embodiments, the protruding features have the same composition as the (e.g., bulk of) the first layer 110. In some embodiments, the recessed features are defined by a structure that is formed of a single composition (e.g., the first layer). In some embodiments, the composition can be, for instance, a polymer, a polymer blend, and/or a polymeric matrix containing nanoparticles dispersed in the polymeric matrix. In some embodiments, the composition can be, for instance, an inorganic material. An advantage of the protruding features consisting of one composition is that often the protruding features can be formed by a relatively simple nanoreplication method, e.g., as described in the Examples below with respect to Film A. In embodiments in which all of the nanofeatures are recessed features, what is meant by a portion of the nanofeatures of the second layer being attached to a portion of the nanofeatures of the first layer is that at least a portion of the recessed features of each layer together define voids (e.g., boundaries of a void are formed by a recessed feature of each of the first layer and the second layer).

The article 1000 of FIG. 1 further comprises a third layer 130 comprising a nanostructured first surface 132 comprising nanofeatures 134 and an opposing second surface 136; and a fourth layer 140 comprising a first major surface 142 attached to a portion of the nanofeatures 134 and an opposing second major surface 144. In this embodiment, the nanofeatures 134 are recessed features 137, and a plurality of voids 135 are defined by the first major surface 142 of the fourth layer 140 and the nanofeatures 134 of the third layer 130. In this embodiment, the opposing second surface 136 of the third layer 130 is attached to the opposing second surface 126 of the second layer; however, it is contemplated that the third layer could instead be attached (either directly or indirectly) to the opposing second surface 116 of the first layer 110.

Any number of additional layers can be used in combination with one or more layers defining enclosed void(s), for instance to provide structural integrity, adhesion, further optical effects, etc. The location of each additional layer is not particularly limited but rather may be selected as desired. For example, the article 1000 of FIG. 1 further comprises a fifth layer 150 attached to the fourth layer 140, in which a first major surface 152 of the fifth layer 150 is attached to the second major surface 144 of the fourth layer. The article 1000 further comprises a sixth layer 160 attached to the opposing second surface 116 of the first layer 110.

Referring now to FIG. 2, a schematic cross-sectional view of an exemplary article 2000 according to the present application is provided. The article 2000 comprises a first layer 210 comprising a nanostructured first surface 212 comprising nanofeatures 214 and an opposing second surface 216; and a second layer 220 comprising a first major surface 222 attached to a portion of the nanofeatures 214 and an opposing second major surface 224. In this embodiment, the nanofeatures 214 are protruding features 219, and a plurality of voids 200 are defined by the first major surface 222 of the second layer 220 and the nanofeatures 214 of the first layer 210. The article 2000 further comprises a third layer 230 comprising a nanostructured first surface 232 comprising nanofeatures 234 and an opposing second surface 236; and a fourth layer 240 comprising a first major surface 242 attached to a portion of the nanofeatures 234 and an opposing second major surface 244. In the embodiment shown in FIG. 2, the nanostructured first surface 232 of the third layer 230 comprises both recessed features 237 and protruding features 239. Alternatively, an article can include just one of recessed features 237 or protruding features 239, such as seen in FIG. 1. In some embodiments, one connected void is present that surrounds many, most, or all of protruding nanofeatures of a nanostructured surface that comprises only protruding features. An advantage of using only recessed features is that the second layer can contact a major surface of the first layer rather than the tops of a number of protruding features, and the resulting article may be less fragile than one having protruding features. The embodiment shown in FIG. 2 includes both individual voids 235 that extend into recessed features 237 and a large connected void 235 that extends around a plurality of protruding features 239.

The embodiment shown in FIG. 2 further comprises a fifth layer 250 having a first major surface 252 attached to the opposing second surface 216 of the first layer and an opposing second major surface 254. The article 200 also comprises a sixth layer 260 having a first major surface 262 attached to the opposing second major surface 254 of the fifth layer 250, and an opposing second major surface 264 attached to the opposing second surface 236 of the third layer. The article 2000 shown in FIG. 2 additionally comprises a seventh layer 270 having a first major surface 272 attached to the opposing second major surface 244 of the fourth layer 240, and an opposing second major surface 274. Further, the article 200 comprises an eighth layer 280 having a first major surface 282 attached to the opposing second major surface 274 of the seventh layer 270. The fifth through eighth layers are shown as an example only. As noted above with respect to FIG. 1, any number of additional layers can be used in combination with one or more layers comprising enclosed void(s), for instance to provide structural integrity, adhesion, further optical effects, etc. The location of each additional layer is not particularly limited but rather may be selected as desired.

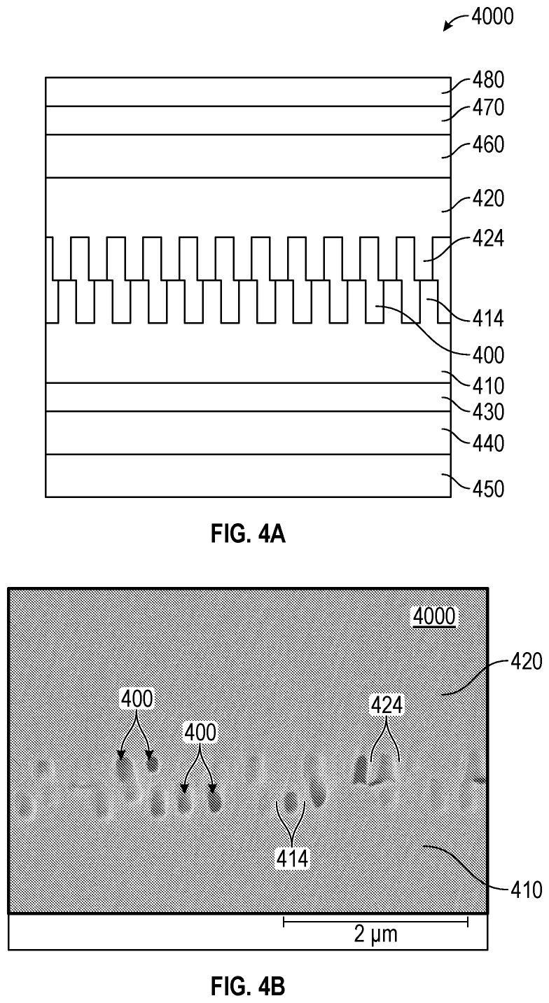

Referring to FIG. 4A, a schematic cross-sectional view of the exemplary article 4000 according to Example 1 is provided. The article 4000 comprises a first layer 410 comprising a nanostructured first surface comprising a plurality of nanofeatures 414, and a second layer 420 comprising a nanostructured first surface comprising a plurality of nanofeatures 424. At least a portion of the nanofeatures 424 of the second layer 420 are attached to at least a portion of the nanofeatures 414 of the first layer 410. The nanostructured first surface of the second layer 420 and the nanostructured first surface of the first layer 410 together define at least one first void 400. The article 4000 according to Example 1 further comprises a plurality of other layers on either side of the first layer 410 and the second layer 420. In particular, the embodiment of FIG. 4A further comprises a third layer 430 that is a polymeric layer, a fourth layer 440 that is a polymeric layer, and a fifth layer 450 that is a release liner. The third layer 430 is directly attached to the first layer 410, the fourth layer 440 is directly attached to the third layer 430, and the fifth layer 450 is directly attached to the fourth layer 440. The embodiment of FIG. 4A further comprises a sixth layer 460 that is a polymeric layer, a seventh layer 470 that is a polymeric layer, and an eighth layer 480 that is a release liner. The sixth layer 460 is directly attached to the second layer 420, the seventh layer 470 is directly attached to the sixth layer 460, and the eighth layer 480 is directly attached to the seventh layer 470.

FIG. 4B provides a scanning electron microscopy (SEM) image of a cross-section of the exemplary article prepared in Example 1 below, showing a portion of the nanofeatures 414 and 424 of the article 4000 defining at least one void 400. Stated another way, a plurality of voids 400 are defined by the space between the first layer 410 and the second layer 420 where a portion of the nanofeatures 414 of the first layer 410 are attached to a portion of the nanofeatures 424 of the second layer 420. It is noted that the cross-section shows a portion of the voids 400 closer to an edge than the center of the voids 400.

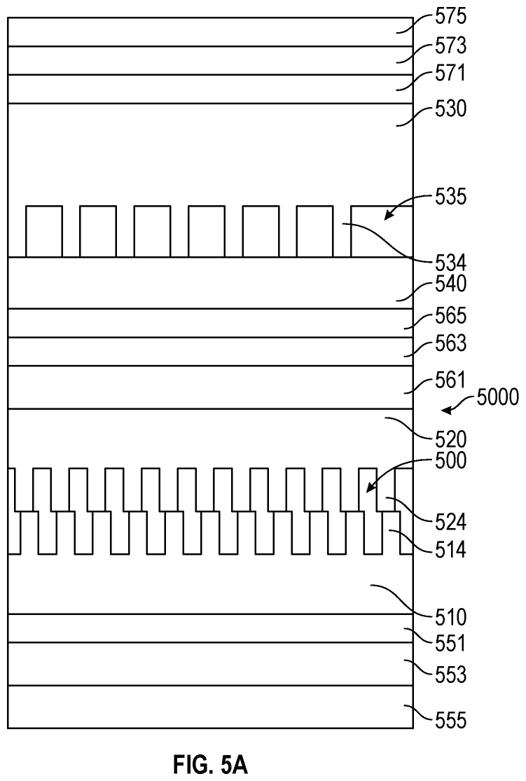

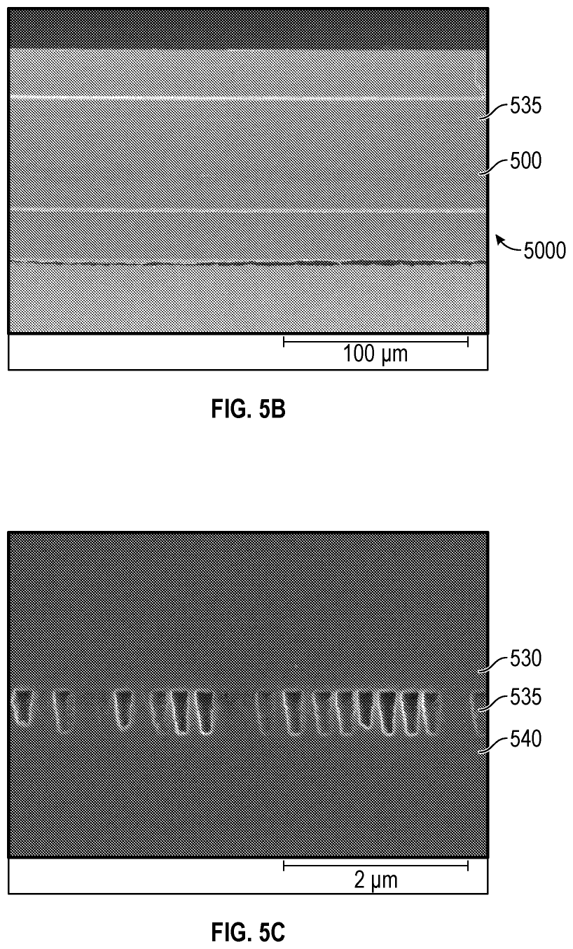

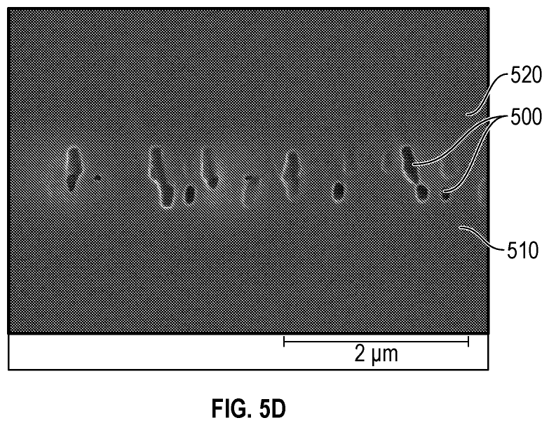

FIG. 5A is a schematic cross-sectional view of the exemplary article of Example 2, according to the present application. The article 5000 comprises a first layer 510 comprising a nanostructured first surface comprising a plurality of nanofeatures 514, and a second layer 520 comprising a nanostructured first surface comprising a plurality of nanofeatures 524. At least a portion of the nanofeatures 524 of the second layer 520 are attached to at least a portion of the nanofeatures 514 of the first layer 510. The nanostructured first surface of the second layer 520 and the nanostructured first surface of the first layer 510 together define at least one first void 500. Further, the article 5000 comprises a third layer 530 comprising a nanostructured first surface comprising a plurality of nanofeatures 534 and a fourth layer 540 comprising a first major surface attached to a portion of the nanofeatures 534. In this embodiment, the nanofeatures 534 are protruding features, and a plurality of second voids 535 are defined by the first major surface of the fourth layer 540 and the nanofeatures 534 of the third layer 530.

The article 5000 according to Example 2 additionally comprises a plurality of other layers, including located on either side of the first layer 510 and the second layer 520. In particular, the embodiment of FIG. 5A further comprises a fifth layer 551 that is a polymeric layer, a sixth layer 553 that is a polymeric layer, and a seventh layer 555 that is a release liner. The fifth layer 551 is directly attached to the first layer 510, the sixth layer 553 is directly attached to the fifth layer 551, and the seventh layer 555 is directly attached to the sixth layer 553. The embodiment of FIG. 5A further comprises an eighth layer 561, a ninth layer 563, and a tenth layer 565, each of which is a polymeric layer. The eighth layer 561 is directly attached to the second layer 520, the ninth layer 563 is directly attached to the eighth layer 561, and the tenth layer 565 is directly attached to each of the ninth layer 563 and the fourth layer 540. The article 5000 also comprises an eleventh layer 571 that is a polymeric layer, a twelfth layer 573 that is a polymeric layer, and a thirteenth layer 575 that is a release liner. The eleventh layer 571 is directly attached to the third layer 530, the twelfth layer 573 is directly attached to the eleventh layer 571, and the thirteenth layer 575 is directly attached to the twelfth layer 573.

FIG. 5B is an SEM image of a cross-section of the exemplary article 5000 prepared in Example 2. The portions including the first void(s) 500 and the second void(s) 535 appear as faint lines in the cross-section. FIG. 5C is an SEM image of a cross-section of an upper portion of the exemplary article of Example 2, in which the third layer 530, the fourth layer 540, and a plurality of voids 535 can be seen.

Similarly, FIG. 5D is an SEM image of a cross-section of a lower portion of the exemplary article of Example 2, in which the first layer 510, the second layer 520, and a plurality of voids 500 can be seen.

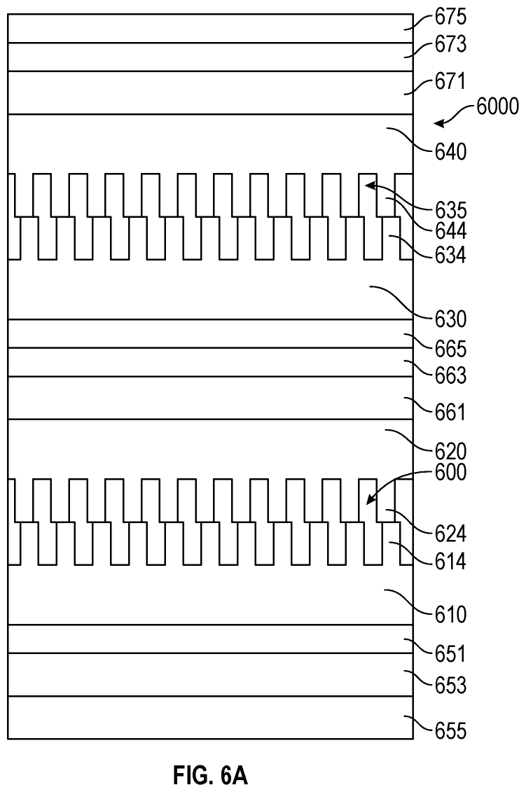

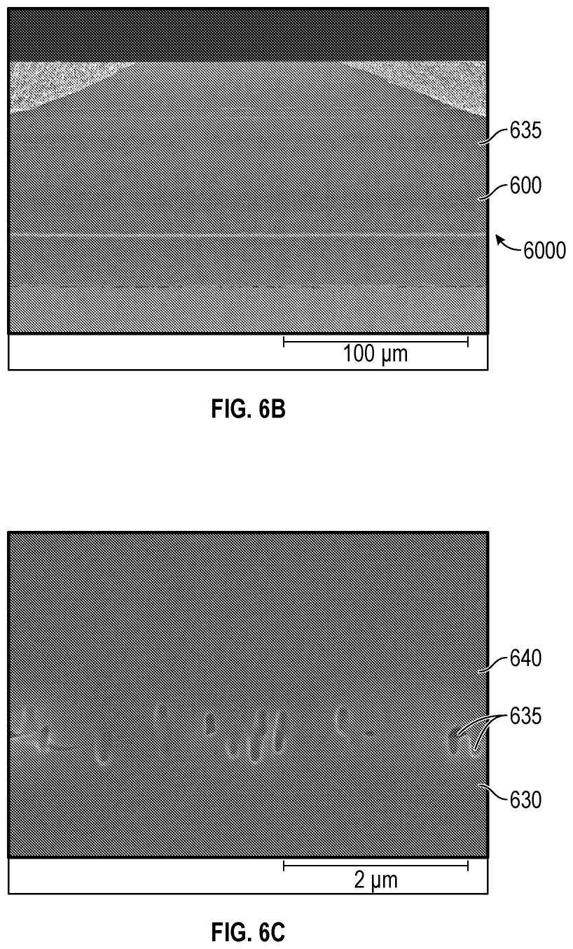

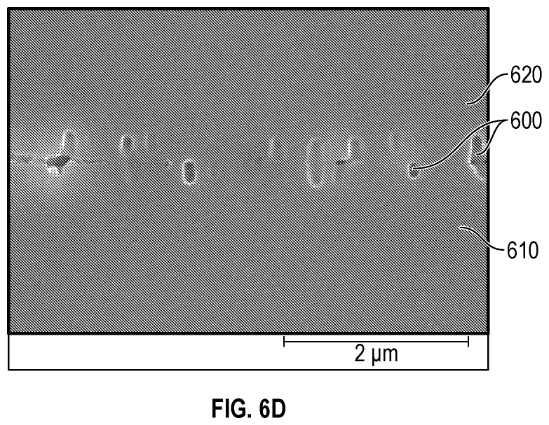

FIG. 6A is a schematic cross-sectional view of the exemplary article of Example 3, according to the present application. The article 6000 comprises a first layer 610 comprising a nanostructured first surface comprising a plurality of nanofeatures 614, and a second layer 620 comprising a nanostructured first surface comprising a plurality of nanofeatures 624. At least a portion of the nanofeatures 624 of the second layer 620 are attached to at least a portion of the nanofeatures 614 of the first layer 610. The nanostructured first surface of the second layer 620 and the nanostructured first surface of the first layer 610 together define at least one first void 600. Further, the article 6000 comprises a third layer 630 comprising a nanostructured first surface comprising a plurality of nanofeatures 634 and a fourth layer 640 comprising a nanostructured first surface comprising a plurality of nanofeatures 644. At least a portion of the nanofeatures 644 of the fourth layer 640 are attached to at least a portion of the nanofeatures 634 of the third layer 630. The nanostructured first surface of the fourth layer 640 and the nanostructured first surface of the third layer 630 together define at least one first void 635. In this embodiment, the nanofeatures 634 and 644 are protruding features, and a plurality of voids 635 are defined by the first major surface of the fourth layer 640 and the nanofeatures 634 of the third layer 630.

The article 6000 according to Example 3 additionally comprises a plurality of other layers, including located on either side of the first layer 610 and the second layer 620. In particular, the embodiment of FIG. 6A further comprises a fifth layer 651 that is a polymeric layer, a sixth layer 653 that is a polymeric layer, and a seventh layer 655 that is a release liner. The fifth layer 651 is directly attached to the first layer 610, the sixth layer 653 is directly attached to the fifth layer 651, and the seventh layer 655 is directly attached to the sixth layer 653. The embodiment of FIG. 6A further comprises an eighth layer 661, a ninth layer 663, and a tenth layer 665, each of which is a polymeric layer. The eighth layer 661 is directly attached to the second layer 620, the ninth layer 663 is directly attached to the eighth layer 661, and the tenth layer 665 is directly attached to each of the ninth layer 663 and the fourth layer 640. The article 6000 also comprises an eleventh layer 671 that is a polymeric layer, a twelfth layer 673 that is a polymeric layer, and a thirteenth layer 675 that is a release liner. The eleventh layer 671 is directly attached to the fourth layer 640, the twelfth layer 673 is directly attached to the eleventh layer 671, and the thirteenth layer 675 is directly attached to the twelfth layer 673.

FIG. 6B is an SEM image of a cross-section of the exemplary article prepared in Example 3. The portions including the first voids 600 and the second voids 635 appear as faint lines in the cross-section. FIG. 6C is an SEM image of a cross-section of an upper portion of the exemplary article of Example 3, in which the third layer 630, the fourth layer 640, and a plurality of voids 635 can be seen. Similarly, FIG. 6D is an SEM image of a cross-section of a lower portion of the exemplary article of Example 3, in which the first layer 610, the second layer 620, and a plurality of voids 600 can be seen.

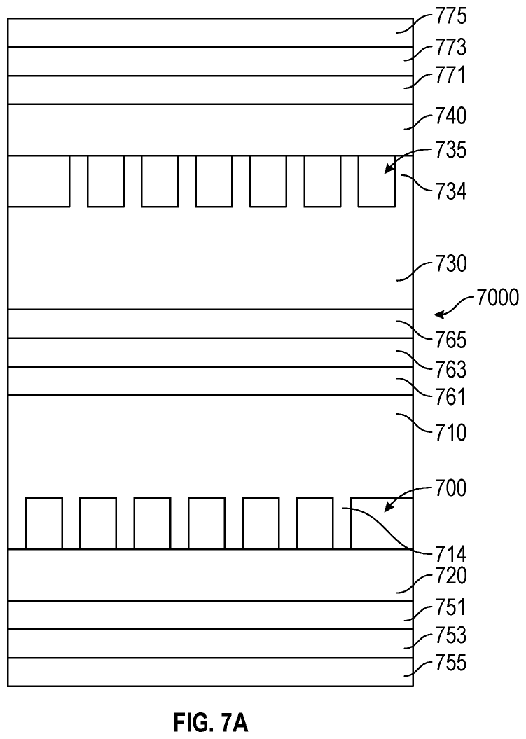

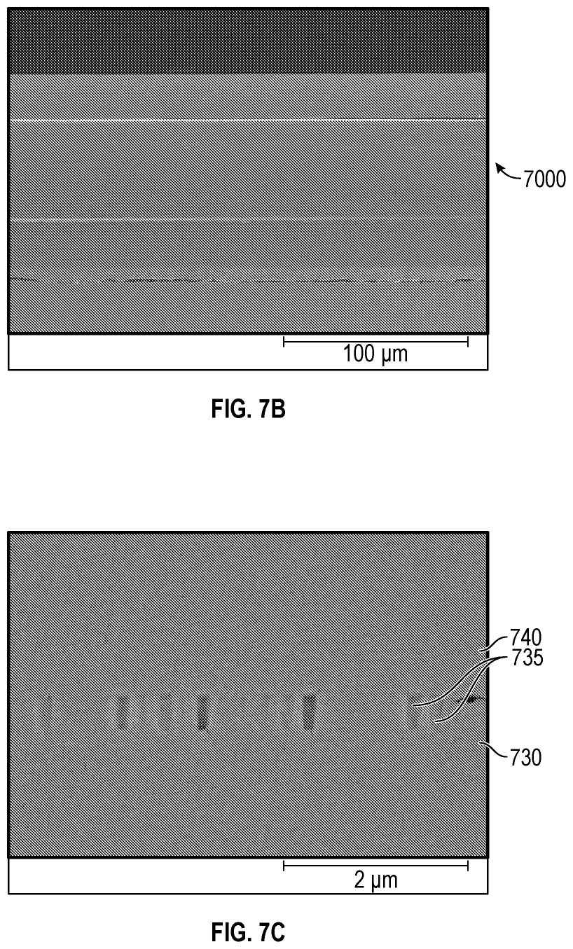

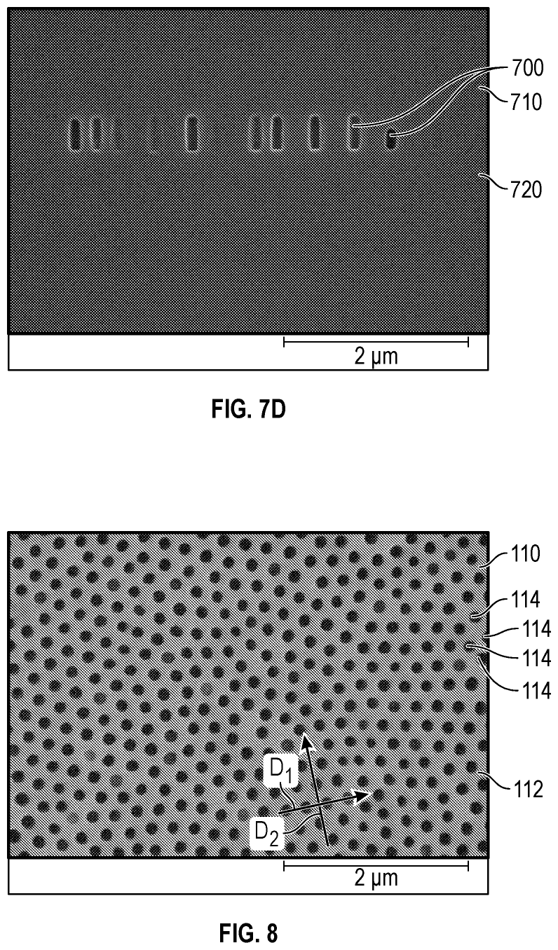

FIG. 7A is a schematic cross-sectional view of the exemplary article of Example 4 according to the present application. The article 7000 comprises a first layer 710 comprising a nanostructured first surface comprising a plurality of nanofeatures 714, and a second layer 720 comprising a first major surface attached to a portion of the nanofeatures 714. In this embodiment, the nanofeatures 714 are protruding features, and a plurality of voids 700 are defined by the first major surface of the second layer 720 and the nanofeatures 714 of the first layer 710. Further, the article 7000 comprises a third layer 730 comprising a nanostructured first surface comprising a plurality of nanofeatures 734 and a fourth layer 740 comprising a first major surface attached to a portion of the nanofeatures 734. The nanofeatures 734 are protruding features, and a plurality of voids 735 are defined by the first major surface of the fourth layer 740 and the nanofeatures 734 of the third layer 730.

The article 7000 according to Example 4 additionally comprises a plurality of other layers, including located on either side of the first layer 710 and the second layer 720. In particular, the embodiment of FIG. 7A further comprises a fifth layer 751 that is a polymeric layer, a sixth layer 753 that is a polymeric layer, and a seventh layer 755 that is a release liner. The fifth layer 751 is directly attached to the second layer 720, the sixth layer 753 is directly attached to the fifth layer 751, and the seventh layer 755 is directly attached to the sixth layer 753. The embodiment of FIG. 7A further comprises an eighth layer 761, a ninth layer 763, and a tenth layer 765, each of which is a polymeric layer. The eighth layer 761 is directly attached to the first layer 710, the ninth layer 763 is directly attached to the eighth layer 761, and the tenth layer 765 is directly attached to each of the ninth layer 763 and the third layer 530. The article 7000 also comprises an eleventh layer 771 that is a polymeric layer, a twelfth layer 773 that is a polymeric layer, and a thirteenth layer 775 that is a release liner. The eleventh layer 771 is directly attached to the fourth layer 540, the twelfth layer 773 is directly attached to the eleventh layer 771, and the thirteenth layer 775 is directly attached to the twelfth layer 773.

FIG. 7B is an SEM image of a cross-section of the exemplary article prepared in Example 4. FIG. 7C is an SEM image of a cross-section of an upper portion of the exemplary article of Example 4, in which the third layer 730, the fourth layer 740, and a plurality of voids 735 can be seen. Similarly, FIG. 7D is an SEM image of a cross-section of a lower portion of the exemplary article of Example 4, in which the first layer 710, the second layer 720, and a plurality of voids 700 can be seen.

Optionally, many of the layers may each be substantially planar. As used herein, “substantially planar” with respect to a layer means that a surface of the layer is essentially free of recesses and/or protrusions extending above and/or below a plane of the layer, the recesses and/or protrusions having a depth or height of greater than 100 micrometers, 90 micrometers, 80 micrometers, 70 micrometers, 60 micrometers, 50 micrometers, 40 micrometers, 30 micrometers, 25 micrometers, 20 micrometers, 15 micrometers, 10 micrometers, 9 micrometers, 8 micrometers, 7 micrometers, 6 micrometers, 5 micrometers, 4 micrometers, 3 micrometers, 2 micrometers, or greater than 1 micrometer. Typically, recesses and/or protrusions have a depth or height of less than 1 millimeter, such as 900 micrometers or less, 800 micrometers, 700 micrometers, 600 micrometers, 500 micrometers, 400 micrometers, or 300 micrometers or less. The depth or height of a recess or a protrusion present on a layer surface can be measured with a confocal microscope.

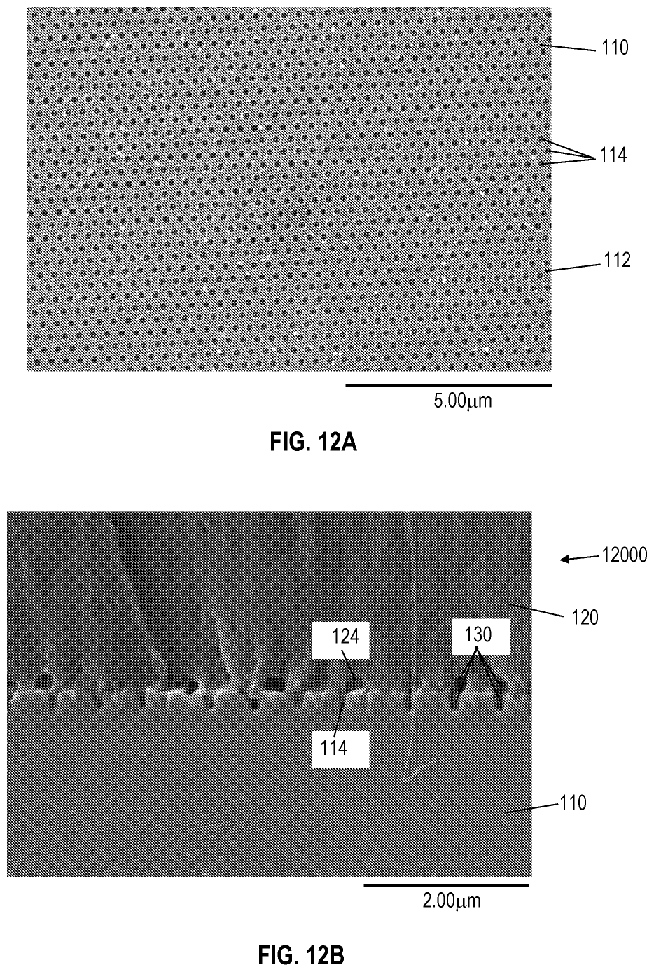

In some embodiments, a layer comprising a nanostructured first surface comprising nanofeatures and an opposing second surface is an inorganic layer, such as a ceramic layer. For instance, co-owned International Application Publication No. WO 2018/044565 (Humpal et al.) describes forming shaped gel, aerogel, and sintered articles. A shaped gel article is a polymerized product formed by casting a sol containing surface-modified colloidal silica particles into a mold cavity followed by polymerizing the sol. The shaped gel retains both a size and a shape identical to the mold cavity. Removal of organic solvent medium from the shaped gel article provides an aerogel article. Heating a shaped gel article to remove organic matrix from the polymerized product provides a sintered article. Shaped gel articles can replicate the features of a mold cavity even if the cavity dimensions are quite small. This is possible at least when the casting sol has a relatively low viscosity and contains silica particles having an average particle size no greater than 100 nanometers. FIG. 12A provides an SEM image of a top view of a portion of a nanostructured first layer 110 including recessed nanofeatures 114 in the surface 112 of Structured Sample B, which was formed using the method described in WO 2018/044565.

Suitable inorganic materials are not limited to silicon oxide, but can comprise an oxide, a nitride, a carbide, or a boride of a metal or a nonmetal, or combinations thereof. In some embodiments, the inorganic material comprises an oxide of titanium, indium, tin, tantalum, zirconium, niobium, aluminum, silicon, or combinations thereof. For instance, suitable oxides include silica, aluminum oxides such as alumina, titanium oxides such as titania, indium oxides, tin oxides, indium tin oxide (ITO), hafnium oxide, tantalum oxide, zirconium oxide, niobium oxide, and combinations thereof. When an inorganic material is employed as a layer comprising a nanostructured first surface comprising nanofeatures, the article may be useful as an optical element, such as a diffraction grating.

Optionally, any one or more of the layers comprises a polymeric material (i.e., a three-dimensionally continuous polymeric phase). The layer may comprise a crosslinked material or a crosslinkable material. In some embodiments, each of the first through fourth layers is an organic layer, such as a polymeric layer. Any one or more of the layers may comprise a crosslinked material or a crosslinkable material. Any one or more of the nanostructured layers may have a refractive index in the range of 1.2 to 2.4, or in the range of 1.4 to 1.75, for example. The refractive index refers to the refractive index measured at 632 nm, unless specified differently or unless the context clearly indicates differently. In some embodiments, one or more of the nanostructured layer(s) has a refractive index of 1.3 or greater, 1.5 or greater, 1.6 or greater, 1.7 or greater, or 1.75 or greater; and a refractive index of 2.4 or less, 2.3 or less, 2.2 or less, 2.1 or less, or 2.0 or less. Articles according to the present disclosure provide a refractive index contrast (absolute value of the difference in the refractive index of a nanostructured first layer and the refractive index of the void(s)) across an opposing second surface of the first layer (e.g., due at least partially to the presence of the void(s)). In some embodiments, the refractive index contrast is in a range of 0.1 to 1.0, 0.3 to 1.0, or 0.5 to 1.0.

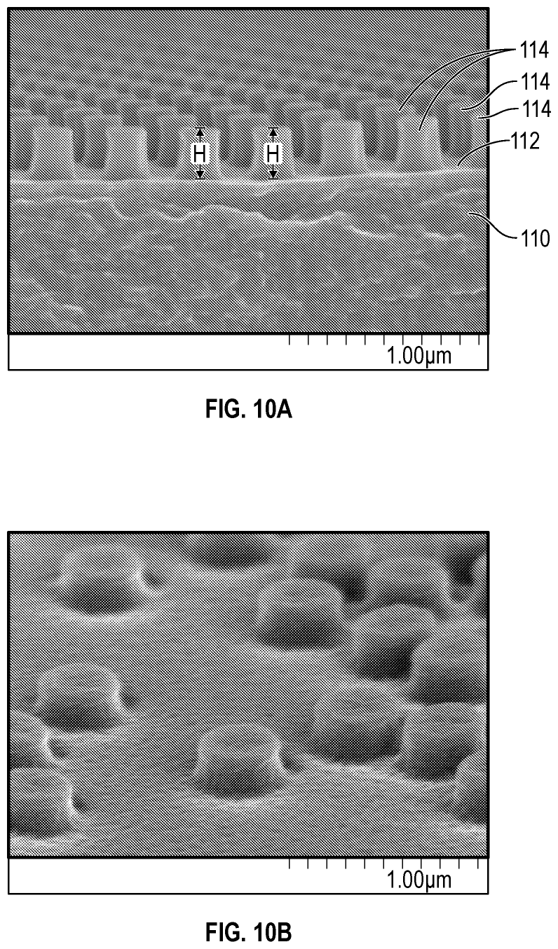

Nanostructures are structures having at least one dimension, such as width or height, less than 1 micrometer. Nanostructured surfaces can be made using a tool having a nanostructured surface. In some embodiments, the tool includes a plurality of particles partially embedded in a substrate. Useful techniques for making the tool are described in U.S. Publication No. 2014/0193612 (Yu et al.) and U.S. Pat. No. 8,460,568 (David et al.). The nanostructured surface of the tool can be characterized by atomic force microscopy (AFM). Further details on useful nanostructured surfaces and methods of making the nanostructured surfaces can be found as described in PCT Publication Nos. WO 2009/002637A2 (Zhang et al.) and WO 2017/205174 (Freier et al.). Referring to FIG. 10A, an SEM of a first layer 110 is shown. The first layer 110 comprises a nanostructured first surface 112 comprising nanofeatures 114.

Examples of characteristics of nanofeatures include pitch, height, depth, aspect ratio, diameter, sidewall angle, and shape. Pitch refers to the distance between adjacent nanofeatures, typically measured from their topmost portions. Height refers to the height of protruding nanofeatures measured from their base (in contact with the underlying layer) to the topmost portion. Depth refers to the depth of recessed nanofeatures measured from their topmost portion (the opening at a major surface of the layer) to the lowermost portion. Aspect ratio refers to the ratio of the cross-sectional width (widest portion) to height or depth of the nanofeatures. Diameter refers to the longest line that can be drawn across a nanofeature from one surface, through a center point, and to an opposing surface at a point along the height or depth of a nanofeature. Sidewall angle refers to the angle formed between a sidewall of a nanofeature and the major surface of the layer from which the nanofeature protrudes or into which the nanofeature recedes. The sidewall angle may differ at various points along the height or depth of a nanofeature. Shape refers to the cross-sectional shape of the nanofeatures. Optionally, the cross-sectional shapes (and diameters) may differ at various points along the height or depth of a nanofeature.

As shown in FIG. 10A, in certain embodiments, the nanostructured first surface 112 of the first layer 110 comprises nanofeatures 114 having a regular height H, whereas in other embodiments the nanostructured first surface 112 of the first layer 110 comprises nanofeatures 114 having varying heights. This can depend on the method of forming the nanostructured surface. In any embodiment according to the present disclosure at least one dimension of height H or width W of the nanofeatures is less than a micrometer, to provide the required small size of the features. In some embodiments, a (e.g., average) height H of the nanofeatures is less than a micrometer, 950 nanometers (nm) or less, 900 nm or less, 850 nm or less, 800 nm or less, 750 nm or less, 700 nm or less, 650 nm or less or 600 nm or less; and a height H of the nanofeatures is 5 nm or greater, 10 nm or greater, 20 nm or greater, 30 nm or greater, 50 nm or greater, 75 nm or greater, 100 nm or greater, 150 nm or greater, 200 nm or greater, 250 nm or greater, 300 nm or greater, 350 nm or greater, 400 nm or greater, 450 nm or greater, or 500 nm or greater. In some embodiments, a (e.g., average) width W of the nanofeatures is less than a micrometer, 950 nanometers (nm) or less, 900 nm or less, 850 nm or less, 800 nm or less, 750 nm or less, 700 nm or less, 650 nm or less or 600 nm or less; and a width W of the nanofeatures is 5 nm or greater, 10 nm or greater, 20 nm or greater, 30 nm or greater, 50 nm or greater, 75 nm or greater, 100 nm or greater, 150 nm or greater, 200 nm or greater, 250 nm or greater, 300 nm or greater, 350 nm or greater, 400 nm or greater, 450 nm or greater, or 500 nm or greater.

The nanostructured surfaces can each comprise nanofeatures such as, for example, nano-columns, or continuous nano-walls comprising nano-columns. Referring to each of FIG. 1 and FIG. 2, in certain embodiments, the nanofeatures 134 comprise at least one non-linear surface 131 in at least one direction. For instance, some of the nanofeatures 134 shown in FIG. 1 have a curved surface 131 (e.g., at a lower surface of the recessed features 134), and at least some of the nanofeatures 214 shown in FIG. 2 have a curved surface 215 (e.g., at a side wall surface of the protruding features 214). Any shape conveniently formed by a nanoreplication process can be employed for the nanofeatures (e.g., prisms, ridges, linear and/or curved polygons). As used herein, “nanoreplication” refers to a process of molding a nanostructured surface from another nanostructured surface using, for example, curable or thermoplastic materials. Nanoreplication is further described, for instance, in “Micro/Nano Replication”, Shinill Kang, John Wiley & Sons, Inc., 2012, Chapters 1 and 5-6. The nanofeatures optionally have steep side walls that are generally perpendicular to the opposing second surface of the first or second layer. For instance, referring to FIG. 1, some of the nanofeatures 114 have steep side walls 111 generally perpendicular to the opposing second surface 116 of the first layer 110.

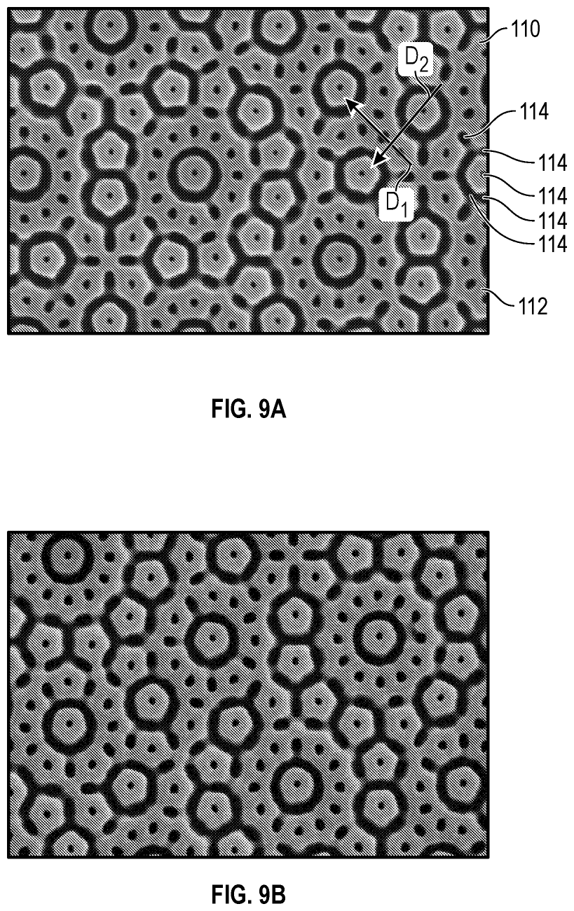

Referring to FIG. 8, certain individual nanofeatures 114 can be spaced equally in one direction D1 along the nanostructured first surface 112 but not in an orthogonal direction D2. In some embodiments, certain individual nanofeatures 114 are spaced equally in at least two directions D1 and D2 along the nanostructured first surface 112 (not shown). Referring to FIG. 9A, certain individual nanofeatures 114 not spaced equally in either direction D1 along the nanostructured first surface 112 or in an orthogonal direction D2.

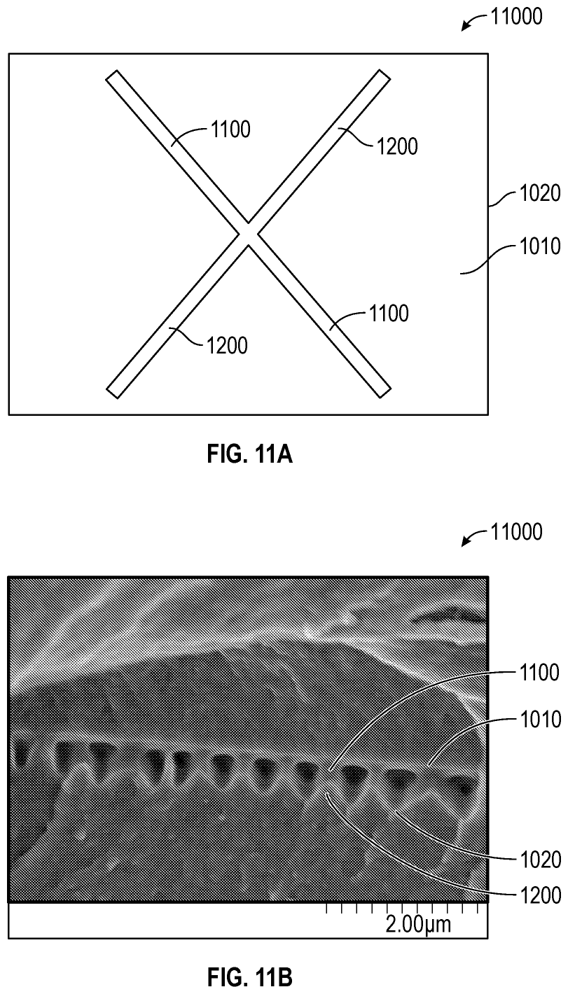

In some embodiments, each of the nanostructured first surface of the first layer and the nanostructured first surface of a second layer comprises a line of nanofeatures, and wherein the line of nanofeatures of the first layer cross the line of nanofeatures of the second layer at an angle of 80 to 100 degrees. For instance, referring to FIG. 11A, a schematic diagram is provided of atop view of an exemplary article in which two lines of nanofeatures cross each other. More particularly, the article 11000 shows a first surface 1010 of a first layer comprising a line of nanofeatures 1100 and a first surface 1020 of a second layer (underneath the first surface 1010) comprising a line of nanofeatures 1200. The linear nanostructures 1100 and 1200 are bonded directly where the linear direction of the two surfaces are rotated azimuthally so the linear directions are at about 90 degrees, thereby forming an “X” pattern when viewing from the top or bottom of one of the major surfaces. FIG. 11B provides an SEM image of a cross-section of a portion of the exemplary article 1100 of Example 6. Article 1100 comprises a first surface 1010 of a first layer, a first surface 1020 of a second layer, and the intersection of the linear nanofeatures 1100 and 1200.

In any embodiment, any one or more of the layers has an average thickness of greater than 50 nm, such as 100 nm or greater, 200 nm or greater, 300 nm or greater, 400 nm or greater, 500 nm or greater, 700 nm or greater, 900 nm or greater, 1 micrometer or greater, 1.25 micrometers or greater, 1.5 micrometers or greater, 1.75 micrometers or greater, 2 micrometers or greater, 2.25 micrometers or greater, 2.5 micrometers or greater, 2.75 micrometers or greater, or 3 micrometers or greater; and an average thickness of 1 millimeter (mm) or less, 0.75 mm or less, 0.5 mm or less, 0.25 mm or less, 0.1 mm or less, 0.05 mm or less, or 0.01 mm or less. In select embodiments, any of the layers (e.g., the second layer) is nonporous.

In certain embodiments, any one or more layers (e.g., a planar layer that contacts a nanostructured surface) comprises a polymeric film. A polymeric “film” is a polymer material in the form of a generally flat sheet that is sufficiently flexible and strong to be processed in a roll-to-roll fashion. Polymeric films used in articles described herein are sometimes referred to as base films. By roll-to-roll, what is meant is a process where material is wound onto or unwound from a support, as well as further processed in some way. Examples of further processes include coating, slitting, blanking, and exposing to radiation, or the like. Polymeric films can be manufactured in a variety of thicknesses, ranging in general from about 5 micrometers to 1000 micrometers. Similarly, any one or more nanostructured layer can comprise a film that is generally flat other than the nanostructured surface.

Referring to FIGS. 4-7, suitable fifth through twelfth layers comprise inorganic materials and organic materials; e.g., comprising a polymeric layer. Any one or more of the fifth through twelfth layers may be referred to as substrates. Suitable materials for a polymer substrate include copolyester polymers such as polyethylene terephthalate (PET) and glycol modified polyethylene terephthalate (PETg), cyclo-olefin polymer (COP), cyclo-olefin copolymer (COC), poly(ethylenenaphthalate) (PEN), polycarbonate (PC), acrylate polymers such as alicyclic acrylate or poly(methylmethacrylate) (PMMA), polyimide (PI), polysulfone, and cast cellulose diacetate, and mixtures or copolymers including these materials. A thickness of a substrate is not particularly limited, and may range from a thickness of 5 micrometers to 1 centimeter, 10 micrometers to 500 millimeters, or 50 micrometers to 250 millimeters. Stated another way, the polymer substrate may have a thickness of 5 micrometers or more, 7 micrometers or more, 10 micrometers or more, 20 micrometers or more, 35 micrometers or more, 50 micrometers or more, 75 micrometers or more, 100 micrometers or more, 250 micrometers or more, 500 micrometers or more, 750 micrometers or more, or 1 millimeter or more; and 1 centimeter or less, 9 millimeters or less, 8 millimeters or less, 7 millimeters or less, 6 millimeters or less, 5 millimeters or less, 3.5 millimeters or less, 2.5 millimeters or less, 1 millimeter or less, 0.50 millimeters or less, 0.25 millimeters or less, or 0.10 millimeters or less. Further, additional suitable substrates could include painted or graphics printed substrates including metals, plastics, and glass.

Optionally, in any article according to the present disclosure, any substantially planar layer included comprises a low-birefringent layer. By “low-birefringent” is meant a layer that has a retardation of 25 nm or less. Suitable materials for a low-birefringent layer include for instance polysulfone, acrylate polymers such as polymethyl methacrylate and alicyclic acrylate, polycarbonate polymers, cycloolefin polymers and copolymers, copolyester polymers (e.g., PETg), and cast cellulose diacetate.

Preferably, the article is transparent to visible light. An advantage to having the article transparent to visible light is its suitability for numerous applications, for instance optical information displays and OLED devices.

Referring to FIGS. 1-2 and 4-7, examples of suitable materials for any one or more of the first layer, the second layer, the third layer, or the fourth layer, include the following: high index organic materials; a nanoparticle filled polymer material; polymers filled with high index inorganic materials; and high index conjugated polymers. Examples of high index polymers and monomers are described in C. Yang, et al., Chem. Mater. 7, 1276 (1995), and R. Burzynski, et al., Polymer 31, 627 (1990) and U.S. Pat. No. 6,005,137, all of which are incorporated herein by reference to the extent that they do not contradict the present description. Examples of polymers filled with high index inorganic materials are described in U.S. Pat. No. 6,329,058. Examples of nanoparticles for the nanoparticle filled polymer material include the following high index materials: TiO₂, ZrO₂, H_{f}O₂, or other inorganic materials. In some embodiments, suitable materials any one or more of the first through fourth layers, include a low refractive index material, such as those described in U.S. Pat. No. 8,012,567 (Gaides et al.); or an ultralow refractive index material, such as those described in U.S. Pat. App. Pub. No. 2012/0038990 (Hao et al.). In select embodiments, any one or more of the first through fourth layers comprises an acrylic polymer or copolymer, such as at least one polymerizable component selected from (meth)acrylate monomers, (meth)acrylate oligomers, and mixtures thereof. As used herein, “monomer” or “oligomer” is any substance that can be converted into a polymer. The term “(meth)acrylate” refers to both acrylate and methacrylate compounds. In select embodiments, the first layer and the second layer, and/or the third layer and the fourth layer, comprise the same material.

In some embodiments, a polymerizable composition used for forming any one or more of the first through fourth layers comprises (e.g. solely) a crosslinking agent as the (meth)acrylate monomer comprising at least three (meth)acrylate functional groups. In some embodiments, the crosslinking monomer comprises at least four, five or six (meth)acrylate functional groups. Acrylate functional groups tend to be favored over (meth)acrylate functional groups. Preferred commercially available crosslinking agents include for example trimethylolpropane triacrylate (commercially available from Sartomer Company, Exton, Pa., under the trade designation “SR351”), ethoxylated trimethylolpropane triacrylate (commercially available from Sartomer Company, under the trade designation “SR454”), pentaerythritol tetraacrylate, pentaerythritol triacrylate (commercially available from Sartomer Company under the trade designation “SR444”), dipentaerythritol pentaacrylate (commercially available from Sartomer Company under the trade designation “SR399”), ethoxylated pentaerythritol tetraacrylate, ethoxylated pentaerythritol triacrylate (commercially available from Sartomer under the trade designation “SR494”), dipentaerythritol hexaacrylate, and tris(2-hydroxy ethyl) isocyanurate triacrylate (commercially available from Sartomer under the trade designation “SR368”).

Useful multi-(meth)acrylate monomers and oligomers include:

(a) di(meth)acryl containing monomers such as 1,3-butylene glycol diacrylate, 1,4-butanediol diacrylate, 1,6-hexanediol diacrylate, 1,6-hexanediol monoacrylate monomethacrylate, ethylene glycol diacrylate, alkoxylated aliphatic diacrylate, alkoxylated cyclohexane dimethanol diacrylate, alkoxylated hexanediol diacrylate, alkoxylated neopentyl glycol diacrylate, caprolactone modified neopentylglycol hydroxypivalate diacrylate, caprolactone modified neopentylglycol hydroxypivalate diacrylate, cyclohexanedimethanol diacrylate, diethylene glycol diacrylate, dipropylene glycol diacrylate, ethoxylated bisphenol A diacrylate, hydroxypivalaldehyde modified trimethylolpropane diacrylate, neopentyl glycol diacrylate, polyethylene glycol diacrylate, propoxylated neopentyl glycol diacrylate, tetraethylene glycol diacrylate, tricyclodecanedimethanol diacrylate, triethylene glycol diacrylate, and tripropylene glycol diacrylate;

(b) tri(meth)acryl containing monomers such as glycerol triacrylate, trimethylolpropane triacrylate, ethoxylated triacrylates (e.g., ethoxylated trimethylolpropane triacrylate), propoxylated triacrylates (e.g., propoxylated glyceryl triacrylate, propoxylated trimethylolpropane triacrylate), trimethylolpropane triacrylate, and tris(2-hydroxyethyl)isocyanurate triacrylate; and

(c) higher functionality (meth)acryl containing monomers such as ditrimethylolpropane tetraacrylate, dipentaerythritol pentaacrylate, pentaerythritol triacrylate, ethoxylated pentaerythritol tetraacrylate, and caprolactone modified dipentaerythritol hexaacrylate.

In one embodiment, suitable polymerizable compositions include at least one monomeric or oligomeric (meth)acrylate, preferably a urethane (meth)acrylate. Typically, the monomeric or oligomeric (meth)acrylate is multi(meth)acrylate. The term “(meth)acrylate” is used to designate esters of acrylic and methacrylic acids, and “multi(meth)acrylate” designates a molecule containing more than one (meth)acrylate group, as opposed to “poly(meth)acrylate” which commonly designates (meth)acrylate polymers. Most often, the multi(meth)acrylate is a di(meth)acrylate, but it is also contemplated to employ tri(meth)acrylates, tetra(meth)acrylates and so on. Suitable monomeric or oligomeric (meth)acrylates include alkyl (meth)acrylates such as methyl acrylate, ethyl acrylate, 1-propyl acrylate, methyl methacrylate, 2-phenoxyethyl acrylate, tetrahydrofurfuryl acrylate, and t-butyl acrylate. The acrylates may include (fluoro)alkylester monomers of (meth)acrylic acid, the monomers being partially and or fully fluorinated, such as, trifluoroethyl (meth)acrylate.

Examples of commercially available multi(meth)acrylate resins include the DIABEAM series from Mitsubishi Rayon Co., LTD.; the DINACOL series from Nagase & Company, Ltd.; the NK ESTER series from Shin-Nakamura Chemical Co., Ltd.; the UNIDIC series from Dainippon Ink & Chemicals, Inc., the ARONIX series from Toagosei Co., LTD.; the BLENMER series manufactured by NOF Corp.; the KAYARAD series from Nippon Kayaku Co., Ltd., the LIGHT ESTER series and LIGHT ACRYLATE series from Kyoeisha Chemical Co., Ltd.

Oligomeric urethane multi(meth)acrylates may be obtained commercially, for example from IGM Resins under the trade designation “Photomer 6000 Series”, such as “Photomer 6010” and “Photomer 6210”, and also from Sartomer Company under the trade designation “CN 900 Series”, such as “CN966B85”, “CN964” and “CN972”. Oligomeric urethane (meth)acrylates are also available from Surface Specialties, such as available under the trade designations “Ebecryl 8402”, “Ebecryl 8807” and “Ebecryl 4827”. Oligomeric urethane (meth)acrylates may also be prepared by the initial reaction of an alkylene or aromatic diisocyanate of the formula OCN—R3-NCO with a polyol. Most often, the polyol is a diol of the formula HO—R4-OH wherein R3 is a C2-100 alkylene or an arylene group and R4 is a C2-100 alkylene group. Alkylene and arylene groups may include ether or ester groups. The intermediate product is then a urethane diol diisocyanate, which subsequently can undergo reaction with a hydroxyalkyl (meth)acrylate. Suitable diisocyanates include 2,2,4-trimethylhexylene diisocyanate and toluene diisocyanate. Alkylene diisocyanates are generally preferred. A particularly preferred compound of this type may be prepared from hexane diisocyanate, poly(caprolactone)diol and 2-hydroxyethyl methacrylate. In at least some cases, the urethane (meth)acrylate is preferably aliphatic.

The polymerizable compositions can be mixtures of various monomers and or oligomers, having the same or differing reactive functional groups. Polymerizable compositions comprising two or more different functional groups may be used, including the following; (meth)acrylate, epoxy and urethane. The differing functionality may be contained in different monomeric and or oligomeric moieties or in the same monomeric and or oligomeric moiety. For example, a resin composition may comprise an acrylic or urethane resin having an epoxy group and or a hydroxyl group in the side chain, a compound having an amino group and, optionally, a silane compound having an epoxy group or amino group in the molecule.

The compositions are polymerizable using conventional techniques such as thermal cure, photocure (cure by actinic radiation) and or e-beam cure. In one embodiment, the composition is photopolymerized by exposing it to ultraviolet (UV) and or visible light. More generally, a photopolymerizable composition is typically cured using actinic radiation, such as UV radiation, e-beam radiation, visible radiation, or any combination thereof. The skilled practitioner can select a suitable radiation source and range of wavelengths for a particular application without undue experimentation.

Conventional curatives and/or catalysts may be used in the polymerizable compositions and are selected based on the functional group(s) in the composition. Multiple curatives and or catalysts may be required if multiple cure functionality is being used. Combining one or more cure techniques, such as thermal cure, photocure and e-beam cure, is within the scope of the present disclosure.

Furthermore, the polymerizable compositions can comprise at least one other monomer and or oligomer (that is, other than those described above, namely the monomeric or oligomeric (meth)acrylate and the oligomeric urethane (meth)acrylate). This other monomer may reduce viscosity and/or improve thermomechanical properties and/or increase refractive index. Monomers having these properties include acrylic monomers (that is, acrylate and methacrylate esters, acrylamides and methacrylamides), styrene monomers and ethylenically unsaturated nitrogen heterocycles.

Also included are (meth)acrylate esters having other functionality. Compounds of this type are illustrated by the 2-(N-butylcarbamyl)ethyl (meth)acrylates, 2,4-dichlorophenyl acrylate, 2,4,6-tribromophenyl acrylate, tribromophenoxylethyl acrylate, t-butylphenyl acrylate, phenyl acrylate, phenyl thioacrylate, phenylthioethyl acrylate, alkoxylated phenyl acrylate, isobornyl acrylate and phenoxyethyl acrylate. The reaction product of tetrabromobisphenol A diepoxide and (meth)acrylic acid is also suitable. The other monomer may also be a monomeric N-substituted or N,N-disubstituted (meth)acrylamide, especially an acrylamide. These include N-alkylacrylamides and N,N-dialkylacrylamides, especially those containing C1-4 alkyl groups. Examples are N-isopropylacrylamide, N-t-butylacrylamide, N,N-dimethylacrylamide and N,N-diethylacrylamide. The term “(meth)acrylamide” means acrylamide and methacrylamide.

Styrenic compounds suitable for use as the other monomer include styrene, dichlorostyrene, 2,4,6-trichlorostyrene, 2,4,6-tribromostyrene, 4-methylstyrene and 4-phenoxystyrene. Ethylenically unsaturated nitrogen heterocycles include N-vinylpyrrolidone and vinylpyridine.

Photopolymerizable compositions in accordance with the present disclosure typically include at least one photoinitiator. Suitable exemplary photoinitiators are those available under the trade designations OMNIRAD from IGM Resins (Waalwijk, The Netherlands) and include 1-hydroxycyclohexyl phenyl ketone (OMNIRAD 184), 2,2-dimethoxy-1,2-diphenylethan-1-one (OMNIRAD 651), bis(2,4,6 trimethylbenzoyl)phenylphosphineoxide (OMNIRAD 819), 1-[4-(2-hydroxyethoxy)phenyl]-2-hydroxy-2-methyl-1-propane-1-one (OMNIRAD 2959), 2-benzyl-2-dimethylamino-1-(4-morpholinophenyl)butanone (OMNIRAD 369), 2-Dimethylamino-2-(4-methyl-benzyl)-1-(4-morpholin-4-yl-phenyl)-butan-1-one (OMNIRAD 379), 2-methyl-1-[4-(methylthio)phenyl]-2-morpholinopropan-1-one (OMNIRAD 907), Oligo[2-hydroxy-2-methyl-1-[4-(1-methylvinyl)phenyl]propanone] ESACURE ONE (Lamberti S.p.A., Gallarate, Italy), 2-hydroxy-2-methyl-1-phenyl propan-1-one (DAROCUR 1173), 2, 4, 6-trimethylbenzoyldiphenylphosphine oxide (OMNIRAD TPO), and 2, 4, 6-trimethylbenzoylphenyl phosphinate (OMNIRAD TPO-L). Additional suitable photoinitiators include for example and without limitation, benzyl dimethyl ketal, 2-methyl-2-hydroxypropiophenone, benzoin methyl ether, benzoin isopropyl ether, anisoin methyl ether, aromatic sulfonyl chlorides, photoactive oximes, and combinations thereof.

In some embodiments, a cationic photoinitiator is present in compositions that include an epoxy component, for example. Further, a thermal initiator can also optionally be present in a photopolymerizable composition described herein. For instance, a free-radical photoinitiator, a cationic photoinitiator, a thermal photoinitiator, or any combination thereof may be present in a photopolymerizable composition.

Suitable cationic photoinitiators include for instance and without limitation, bis[4-diphenylsulfoniumphenyl]sulfide bishexafluoroantimonate; thiophenoxyphenylsulfonium hexafluoroantimonate (available as CHIVACURE 1176 from Chitec (Houston, Tex.), tris(4-(4-acetylphenyl)thiophenyl)sulfonium tetrakis(pentafluorophenyl)borate, tris(4-(4-acetylphenyl)thiophenyl)sulfonium tris[(trifluoromethyl)sulfonyl]methide, and tris(4-(4-acetylphenyl)thiophenyl)sulfonium hexafluorophosphate, [4-(1-methylethyl)phenyl](4-methylphenyl) iodonium tetrakis(pentafluorophenyl)borate, 4-[4-(2-chlorobenzoyl)phenylthio]phenylbis(4-fluorophenyl)sulfonium hexafluoroantimonate, and aromatic sulfonium salts with anions of (PF₆₋ₘ(CₙF₂ₙ₊₁)ₘ)⁻ where m is an integer from 1 to 5, and n is an integer from 1 to 4 (available as CPI-200K or CPI-200S, which are monovalent sulfonium salts from San-Apro Ltd., (Kyoto, JP) TK-1 available from San-Apro Ltd., or HS-1 available from San-Apro Ltd.)

In some embodiments, a photoinitiator is present in a photopolymerizable composition in an amount of up to about 5% by weight, based on the total weight of polymerizable components in the photopolymerizable composition (e.g., not including components such as particles). In some cases, a photoinitiator is present in an amount of about 0.1-5% by weight, 0.2-5% by weight, or 0.5-5% by weight, based on the total weight of the photopolymerizable composition.

In some embodiments, a thermal initiator is present in a polymerizable composition in an amount of up to about 5% by weight, such as about 0.1-5% by weight, based on the total weight of polymerizable components in the polymerizable composition. Suitable thermal initiators include for instance and without limitation, peroxides such as benzoyl peroxide, dibenzoyl peroxide, dilauryl peroxide, cyclohexane peroxide, methyl ethyl ketone peroxide, hydroperoxides, e.g., tert-butyl hydroperoxide and cumene hydroperoxide, dicyclohexyl peroxydicarbonate, 2,2-azo-bis(isobutyronitrile), and t-butyl perbenzoate. Examples of commercially available thermal initiators include initiators available from DuPont Specialty Chemical (Wilmington, Del.) under the VAZO trade designation including VAZO 67 (2,2′-azo-bis(2-methybutyronitrile)) VAZO 64 (2,2′-azo-bis(isobutyronitrile)) and VAZO 52 (2,2′-azo-bis(2,2-dimethyvaleronitrile)), and LUCIDOL 70 from Elf Atochem North America, Philadelphia, Pa.

When more than one initiator is used (e.g., photoinitiator(s) and/or thermal initiator(s)) in a polymerizable composition to form a layer, the resulting layer typically comprises some remaining amount of both a first initiator or initiator fragment and a second initiator or initiator fragment present in the layer.

Unexpectedly, in some embodiments, the attachment of the first layer and the second layer, and/or of the third layer and the fourth layer, of the article can be sufficiently strong to exhibit a peel force of 10 grams per centimeter (g/cm) or greater, 20 g/cm or greater, 30 g/cm or greater, 40 g/cm or greater, or even 50 g/cm or greater. In some embodiments, at least one the first layer through fourth layers themselves fail instead of two layers separating from each other. By failure of a layer is meant that the layer splits, fractures, fragments, etc., as opposed to maintaining its structural integrity. The peel force (or layer failure) can be determined using the Peel Force test method: Peel force can be evaluated by performing a 180 degree peel test using a Slip/Peel Tester (obtained under the trade designation “IMASS SP-2100” from iMass, Inc, Accord, Mass.). Test samples are cut into 2.54 cm wide strips. A test sample is mounted to the platen of the SP-2100 by attaching one side of the laminate to the platen with 1 inch (2.54 cm) wide double-sided tape (e.g., obtained under the trade designation “3M REPOSITIONABLE TAPE 665” from 3M Co., St. Paul, Minn.). The laminate is separated at the desired interface and the portion of the laminate opposite the platen is attached to the iMass load cell. The platen is advanced at 0.508 cm/s and the force is recorded for 10 s. The average peel force over that time is reported.

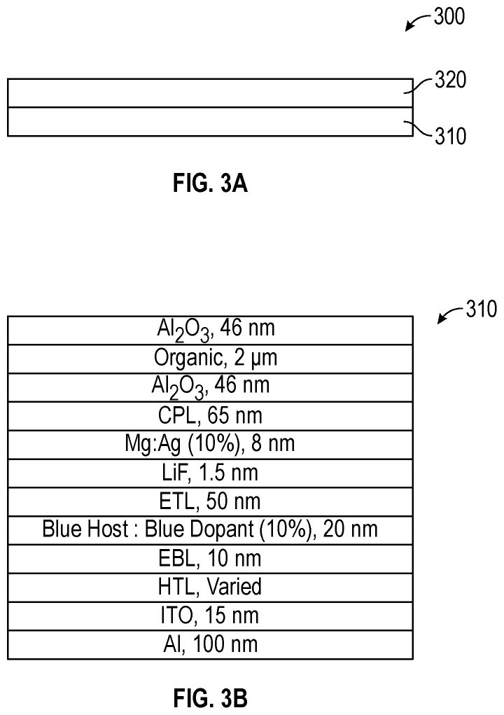

In a second aspect, an optical information display is provided. The optical information display includes an article according to the first aspect described in detail above. Referring to FIG. 3A, a schematic diagram of a cross-section is provided of an exemplary article 300, in which layer 320 is an article including at least one void, as described in detail with respect to the first aspect above. The layer 310 may represent at least one layer of an optical information display. Some examples of information displays include for instance and without limitation, LCD TVs, computer monitors, cell phone displays, OLED phones or TVs, smart watches, inorganic LED displays, and the like.

In a third aspect, an OLED device is provided. The OLED device includes an article according to the first aspect described in detail above. Organic Light Emitting Diode (OLED) devices include at least a thin film of electroluminescent organic material sandwiched between a cathode and an anode, with one or both of these electrodes being capable of transmitting light. When a voltage is applied across the device, electrons and holes are injected from their respective electrodes and recombine in the electroluminescent organic material through the intermediate formation of excitons.

Once the proper values of the design parameters have been identified, an OLED display panel can be made using conventional OLED fabrication processes which may include depositing organic layers by one or more of vacuum deposition, vacuum thermal evaporation, organic vapor phase deposition, and inkjet printing. Useful methods of manufacturing OLED display panels are described in U.S. Pat. Appl. Publ. Nos. 2010/0055810 (Sung et al.), 2007/0236134 (Ho et al.), 2005/0179373 (Kim) and 2010/0193790 (Yeo et al.).

An OLED display often includes an array of pixels, and each pixel can include several subpixels. Typically, each OLED subpixel emits red, blue or green light. In some cases, subpixels may be used which emit white, cyan, magenta, yellow or other colors of light. OLED subpixels include at least one, and oftentimes several, layers of organic material sandwiched between a cathode and an anode. The design of an OLED subpixel includes selecting the thickness, and optical and electronic properties of each layer so that the emitted light has the desired output. The OLED layer architecture is sometimes referred to as the “emissive stack” or OLED “stack.” Referring to FIG. 3B, a schematic diagram is provided of a cross-section of an OLED construction according to Example 1 below. The article according to the first aspect can be included in combination with the OLED construction, for instance for the purpose of reducing a color shift of the OLED. Thus, the article layer 320 can be combined with the OLED portions 312 and 314. As described in U.S. Provisional Application Nos. 62/342,620 (Freier et al.) and 62/414,127 (Erickson et al.), and in PCT Publication No. WO 2017/205174 (Freier et al.), a color-correction component, such as an optical stack including a nanostructured interface, can be placed proximate to an emissive layer of an OLED display panel to reduce the variation in color with view direction without substantially changing the on-axis light output of the display. Other useful color-correction components include partial reflectors which, for example, provides a wavelength dependent reflectivity and transmissivity. Useful partial reflectors are described in U.S. Prov. Appl. Nos. 62/566,654 (Haag et al.) and 62/383,058 (Benoit et al.) and 62/427,450 (Benoit), for example. Other useful color-correction components include polymeric films, which function, for example, as moderate optical diffusers. Useful polymeric films are described in U.S. Pat. Appl. Ser. No. 15/587,929 (Hao et al.) and Ser. No. 15/587,984 (Hao et al.), for example. In some embodiments, an OLED display includes an encapsulant which may include one or more layers disposed adjacent or proximate the emissive stack. Optionally, the emissive stack may contain one or more layers which are disposed between the cathode and the encapsulant. A circular polarizer may be disposed adjacent the encapsulant. In some cases, a touch sensor may be included in the OLED display. The touch sensor may optionally be included between the encapsulant and the circular polarizer. The article according to the first aspect can be disposed between the encapsulant and the viewer; the article according to the first aspect can optionally be disposed between the encapsulant and the circular polarizer or between the encapsulant and the touch sensor.

In some embodiments, a color-correction component can be placed adjacent a top surface of atop emitting OLED or adjacent a bottom surface of a bottom emitting OLED. For instance, referring again to FIG. 3A, an article layer containing at least one void 320 can be disposed adjacent to an emitting surface of an OLED 310. The OLED may be a strong-cavity OLED or a weak-cavity OLED or a no-cavity OLED. Current OLED markets are dominated by active-matrix organic light-emitting diode (AMOLED) displays, which have a top-emissive architecture and currently do not use any light extraction method except for employing a strong microcavity design. This strong cavity design can have high axial efficiency, but the angular color uniformity versus viewing angle is worse than that of liquid crystal displays (LCDs), for example. In some embodiments of the present description, the color-correction component is advantageously used with a strong-cavity OLED, such as an AMOLED, because of the relatively large color shifts typically present in a strong-cavity OLED. In some embodiments, an OLED display includes an encapsulant disposed on emissive layers and a circular polarizer disposed adjacent the encapsulant. In some embodiments, the color-correction component is disposed between the encapsulant and the circular polarizer.

### Methods

Various methods may be employed according to the present disclosure to prepare the article according to the first aspect described above. A suitable method for making an article includes obtaining a first material comprising a nanostructured first surface comprising nanofeatures and an opposing second surface, contacting a second layer comprising a first planar or nanostructured surface with a portion of the nanofeatures, and reacting at least one of the first material or the second material to secure the first layer and the second layer together. The nanofeatures of the first layer and the first planar surface or nanostructured surface of the second layer together define at least one void. In any embodiment, the first layer is contacted with the second layer by laminating the first layer and the second layer together. Lamination of layers is well known, and often involves processes such as subjecting at least one outer major surface of a stack of the layers to a weighted roller, or passing stacked layers through a nip roller line or benchtop laminator. The Examples provide additional details regarding preparing articles according to the present disclosure.

In embodiments including any additional layer (e.g., a fifth layer, a sixth layer, etc.) attached to a major surface of any of the first through fourth layers, the additional layer(s) is preferably attached to one of the first through fourth layers prior to contacting the first layer with the second layer or the third layer with the fourth layer, respectively. For instance, an opposing second surface of the first layer can be attached to a substrate (e.g., a layer) and/or the second layer can have a second major surface that is attached to a substrate (e.g., a layer).

In any embodiment, the first material and/or the second material is reacted by subjecting the first layer and/or the second layer to actinic radiation. Typically, the actinic radiation comprises ultraviolet (UV) light, visible light, e-beam, or any combination thereof. Alternatively, or in addition, the first material and/or the second material is reacted by subjecting the first layer and/or the second layer to heat. An advantage of reacting one or more of the first material or the second material is that the reaction usually creates a stronger connection between the first layer and the second layer than achieved solely by applying physical pressure (e.g., lamination) to the outer major surfaces of the first layer and the second layer, particularly since the major surface of the second layer is typically only in contact with a portion of the nanofeatures instead of in contact with an entire major surface of the first layer. For example, reacting a crosslinkable material may generate crosslinks between the first layer and the second layer. In some embodiments, at least one of the first layer or the second layer comprises a partially cured material and the partially cured material is reacted to secure the first layer and the second layer together. Optionally, the first layer and/or the second layer comprises a photoinitiator, a thermal initiator, or both.

In certain embodiments, the second layer comprises a resin having a solids content of 90% or greater, 92% or greater, 94% or greater, 95% or greater, 96% or greater, 98% or greater, or 99% or greater. Components that are considered “solids” include, for instance and without limitation, polymers, oligomers, monomers, and additives such as initiators and fillers. Typically, only solvents do not fall within the definition of solids, for instance water or organic solvents. In preferred embodiments, the second layer contains less than 5 weight percent of total solvent content, more preferably less than 1 weight percent of total solvent content. In some embodiments, the polymeric material is solvent-free other than any residual solvent (e.g., less than 0.5 weight percent of the second layer).

In embodiments where the first material is an inorganic material, the method optionally comprises reacting the second material to secure the first layer and the second layer together. The second material may be reacted with a functionalized inorganic material. For instance, a coupling agent may be bonded to the inorganic material of the first layer, in particular with the nanostructured first surface of the first layer.

Typically, coupling agents include at least one group that bonds (covalently or non-covalently) with an organic layer, and at least one group that bonds (covalently or non-covalently) to an inorganic layer. Covalent bonding requires that the group reacts with the surface with which it is in contact. For instance, for the coupling agent 2-(3-trimethoxysilylpropylcarbamoyloxy)ethyl prop-2-enoate (K90) having the below structure,

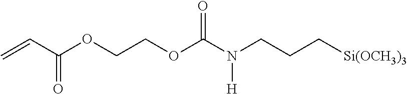

the acrylate group can react with other acrylates in the organic layer adjacent to it to form an acrylate copolymer. Other functional groups that may bond (covalently or non-covalently) with (meth)acrylate coatings may include (meth)acrylate, vinyl, amine, urethane, urea, and thiol functional groups. Likewise, the trimethoxysilyl group can react with one or more metal M (e.g., silicon, aluminum) hydroxide groups of the inorganic layer adjacent to it, e.g., once, twice or three times, to form —Si—O-M- linkages. Other groups, for example acid groups such as carboxylic acid, sulfonic acid, phosphonic acid, or phosphoric acid groups, may be non-covalently bonded via hydrogen bonding with moieties in either the organic or inorganic layers to which the coupling agent is adjacent. The coupling agent before bonding to at least one surface is a distinct compound, and after bonding to at least one surface may be referred to as a “bonded coupling agent”. Accordingly, any inorganic atom, such as silicon, phosphorous, titanium, or zirconium, may still be a part of the bonded coupling agent. When such an inorganic atom is not the same as the metal M, in some embodiments its presence may be detectable by analytical methods.

Suitable coupling agents include for instance and without limitation, functional silanes with hydrolysable alkoxy or chlorinated groups bonded to silicon atoms, with (meth)acrylic silane coupling agents being particularly useful. Such coupling agents are commercially available from Momentive, Gelest, Evonik, Shin-Etsu, and others. Suitable silane materials may include functional groups that bond (covalently or non-covalently) with (meth)acrylate coatings, including (meth)acrylate, vinyl, amine, urethane, urea, and thiol functional groups. Suitable materials may include functional groups that bond (covalently or non-covalently) with inorganic layers such as hydrolysable silane groups, acids, (including phosphoric, phosphonic, sulfonic acid, and carboxylic acid groups) and other groups such as phenols, polyphenols, amines, alcohols and thiols. Included are acrylic silane coupling agent 2-(3-trimethoxysilylpropylcarbamoyloxy)ethyl prop-2-enoate, and others given in U.S. Pat. No. 7,799,888 (Arkles et al.); U.S. Pat. No. 9,029,586 (Arkles et al.); U.S. Pat. No. 9,254,506 (Roehrig et al.); U.S. Pat. No. 9,790,396 (Klun et al.); U.S. Pat. No. 9,982,160 (Klun et al.); U.S. Pat. No. 10,011,735 (Klun et al.), and U.S. Patent Application Publication Nos. 2015/0203707 (Klun et al.) and 2015/0218294 (Klun et al.). Additionally, suitable coupling agents having phosphonic acid groups include those given in U.S. Patent Application Publication No. 2020/0017623 (Ye et al.) and International Application Publication No. WO 2020/046654 (Lin et al.).

A coupling agent is often first bonded with one layer covalently or non-covalently, followed by bonding at least one of the first layer or the coupling agent bonded with the second layer to bond the first layer and the second layer together through a bonded coupling agent. Alternatively, the bonded coupling agent may be formed when the coupling agent bonds with one of the first layer or the second layer and also bonds with another coupling agent compound or other photoreactive component present (e.g., monomer, oligomer, or polymer). This is more likely when the coupling agent is present as part of a coupling agent layer that is at least as thick as the length of the coupling agent compound (or thicker).

Optionally, the bonded coupling agent comprises at least one of silicon, phosphorous, titanium, or zirconium. In some embodiments, the bonded coupling agent comprises at least one functional group selected from an acrylate, a urethane, a urea, an alkylene, a ureido, an isocyanate, an epoxy, an alcohol, an amine, a thiol, a phenol, an amino, an acid, a heteroatom, and at least one of silicon, phosphorous, titanium, or zirconium.

When the nanostructured first surface of the first layer comprises protruding nanofeatures, the bonded coupling agent is bonded to a portion of the protruding nanofeatures. When nanofeatures of the nanostructured first surface of the first layer are all recessed nanofeatures, the bonded coupling agent is bonded to a portion of a major surface of the first layer. In some embodiments, a portion of a nanostructured first surface of a second layer is covalently bonded to a portion of the nanostructured first surface of the first layer via a bonded coupling agent. FIG. 12B is an SEM image showing a cross-section of a portion of the exemplary article 12000 of Example 7 below, in which the material of the first layer 110 is silica and the material of the second layer 120 comprises a polymeric material. The first layer 110 comprises recessed nanofeatures 114 and the second layer 120 comprises recessed nanofeatures 124, and the layers are attached together, defining a plurality of voids 130 between the nanostructured surface of the first layer 110 and the nanostructured surface of the second layer 120. Some of the voids are located between opposing recessed nanofeatures of the first layer and the second layer (e.g., as pointed out in FIG. 12B), while some of the voids are located between a recessed nanofeature of one layer and the surface of the other layer.

As used herein, the term “residue” is used to define the portion of a coupling agent remaining after removal of the groups that can form bonds (covalent bonds or non-covalent) to the first and second layers. Typically, covalent bonds are stronger than non-covalent bonds. As mentioned above, the bonded coupling agent only becomes a residue when both end groups are removed during reaction. For example, the “residue” of coupling agent 2-(3-trimethoxysilylpropylcarbamoyloxy)ethyl prop-2-enoate (K90) shown below:

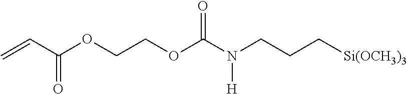

is —CH₂CH₂OC(O)NHCH₂CH₂CH₂—.

Another exemplary coupling agent is

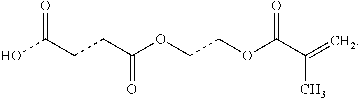

The residue for this coupling agent is —CH₂CH₂OC(O)CH₂CH₂—.

In some cases, such as for

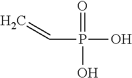

the coupling agent residue is a covalent bond.

The residue of the coupling agent is the “core” of the coupling agent remaining after reaction of the end functional groups with the first layer and the second layer.

In some embodiments, the bonded coupling agent directly bonds the first major surface of the second layer to the nanostructured first surface of the first layer. In such embodiments, the at least one enclosed void is defined by the nanostructured first surface of the first layer and the first major surface of the second layer.

### Select Embodiments of the Disclosure

In a first embodiment, the present disclosure provides an article. The article comprises a) a first layer comprising a nanostructured first surface comprising nanofeatures and an opposing second surface, wherein the nanostructured first surface comprises recessed features, or protruding features formed of a single composition, or both recessed and protruding features; and either b1) or b2). b1) is a second layer comprising a first major surface and an opposing second major surface, the first major surface attached to a portion of the nanofeatures of the first layer, and the nanostructured first surface of the first layer and the first major surface of the second layer together define at least one first void. b2) is a third layer comprising a nanostructured first surface comprising nanofeatures and an opposing second surface, wherein a portion of the nanofeatures of the third layer are attached to a portion of the nanofeatures of the first layer, and the nanostructured first surface of the third layer and the nanostructured first surface of the first layer together define at least one second void. The article includes the proviso that when b1) is present, the article further comprises c) a fourth layer comprising a nanostructured first surface comprising nanofeatures and an opposing second surface. Either the second surface of the fourth layer or the nanostructured first surface of the fourth layer is adjacent either to the second major surface of the second layer or to the second surface of the first layer.

In a second embodiment, the present disclosure provides an article according to the first embodiment, wherein b1) is present.

In a third embodiment, the present disclosure provides an article according to the first embodiment or the second embodiment, wherein b1) is present and the article further comprises d) a fifth layer comprising a first major surface and an opposing second major surface, wherein the first major surface is attached to a portion of the nanofeatures of the fourth layer. The nanostructured first surface of the fourth layer and the first major surface of the fifth layer together define at least one third void.

In a fourth embodiment, the present disclosure provides an article according to the first embodiment, wherein b2) is present and the article further comprises e) a sixth layer comprising a nanostructured first surface comprising nanofeatures and an opposing second surface; and f) a seventh layer comprising a first major surface and an opposing second major surface, wherein the first major surface is attached to a portion of the nanofeatures of the sixth layer. The nanostructured first surface of the sixth layer and the first major surface of the seventh layer together define at least one fourth void. Either the second surface of the sixth layer or the second major surface of the seventh layer is adjacent either to the second major surface of the second layer or to the second surface of the first layer.

In a fifth embodiment, the present disclosure provides an article according to the first embodiment, wherein b2) is present and the article further comprises g) an eighth layer comprising a nanostructured first surface comprising nanofeatures and an opposing second surface; and h) a ninth layer comprising a nanostructured first surface comprising nanofeatures and an opposing second surface, wherein a portion of the nanofeatures of the ninth layer are attached to a portion of the nanofeatures of the eighth layer. The nanostructured first surface of the ninth layer and the nanostructured first surface of the eighth layer together define at least one fifth void. Either the second surface of the eighth layer or the second surface of the ninth layer is adjacent to either the second surface of the third layer or the second surface of the first layer.

In a sixth embodiment, the present disclosure provides an article according to the first embodiment, wherein b1) is present and the article further comprises i) a tenth layer comprising a nanostructured first surface comprising nanofeatures and an opposing second surface; and j) an eleventh layer comprising a nanostructured first surface comprising nanofeatures and an opposing second surface, wherein a portion of the nanofeatures of the eleventh layer are attached to a portion of the nanofeatures of the tenth layer. The nanostructured first surface of the eleventh layer and the nanostructured first surface of the tenth layer together define at least one sixth void. Either the second surface of the tenth layer or the second surface of the eleventh layer is adjacent to either the second major surface of the second layer or the second surface of the first layer.

In a seventh embodiment, the present disclosure provides an article according to any of the first through sixth embodiments, further comprising a twelfth layer disposed adjacent to either the second major surface of the second layer or the second surface of the first layer.

In an eighth embodiment, the present disclosure provides an article according to the seventh embodiment, wherein the twelfth layer is a low bi-refringent layer.

In a ninth embodiment, the present disclosure provides an article according to any of the first through eighth embodiments, further comprising a thirteenth layer disposed adjacent to either the second major surface of the second layer or the second surface of the first layer.

In a tenth embodiment, the present disclosure provides an article according to the ninth embodiment, wherein the thirteenth layer comprises a crosslinked material or a crosslinkable material.

In an eleventh embodiment, the present disclosure provides an article according to any of the first through third or sixth through ninth embodiments, wherein the second layer is substantially planar.

In a twelfth embodiment, the present disclosure provides an article according to any of the first through eleventh embodiments, wherein at least one of the first through sixth voids is present and at least one of the first through sixth voids contains a gas.

In a thirteenth embodiment, the present disclosure provides an article according to any of the first through twelfth embodiments, wherein the first layer is an organic layer.

In a fourteenth embodiment, the present disclosure provides an article according to any of the first through thirteenth embodiments, wherein the first layer comprises a polymeric material.

In a fifteenth embodiment, the present disclosure provides an article according to any of the first through fourteenth embodiments, wherein the second layer or the third layer comprises a polymeric material.

In a sixteenth embodiment, the present disclosure provides an article according to any of the first through fifteenth embodiments, wherein the first layer and either the second layer or the third layer comprise the same material.

In a seventeenth embodiment, the present disclosure provides an article according to any of the first through sixteenth embodiments, wherein at least one of the first layer, the second layer, or the third layer comprises a crosslinked material or a crosslinkable material.

In an eighteenth embodiment, the present disclosure provides an article according to any of the first through seventeenth embodiments, wherein at least one of the first layer, the second layer, or the third layer comprises an acrylic polymer or copolymer.

In a nineteenth embodiment, the present disclosure provides an article according to any of the first through eighteenth embodiments, wherein at least one of the first layer, the sixth layer, the eighth layer, the ninth layer, the tenth layer, or the eleventh layer comprises nanofeatures having a height of less than a micrometer.

In a twentieth embodiment, the present disclosure provides an article according to any of the first through nineteenth embodiments, wherein at least one of the first layer, the sixth layer, the eighth layer, the ninth layer, the tenth layer, or the eleventh layer comprises nanofeatures having a width of less than a micrometer.

In a twenty-first embodiment, the present disclosure provides an article according to any of the first through twentieth embodiments, wherein at least one of the first layer, the sixth layer, the eighth layer, the ninth layer, the tenth layer, or the eleventh layer comprises nanofeatures having at least one non-linear surface in at least one direction.

In a twenty-second embodiment, the present disclosure provides an article according to any of the first through twenty-first embodiments, wherein at least one of the first layer, the sixth layer, the eighth layer, the ninth layer, the tenth layer, or the eleventh layer comprises nanofeatures having recessed features.

In a twenty-third embodiment, the present disclosure provides an article according to any of the first through twenty-second embodiments, wherein at least one of the second layer or the third layer has an average thickness of greater than 50 nanometers, 100 nanometers, 500 nanometers, 1 micrometer, 2 micrometers, or 3 micrometers.

In a twenty-fourth embodiment, the present disclosure provides an article according to any of the first through twenty-third embodiments, wherein b1) is present and the second layer is nonporous.

In a twenty-fifth embodiment, the present disclosure provides an article according to any of the first through twenty-fourth embodiments, wherein the nanostructured first surface of the first layer has only recessed features.

In a twenty-sixth embodiment, the present disclosure provides an article according to any of the first through twenty-fourth embodiments, wherein the nanostructured first surface of the first layer comprises protruding features.

In a twenty-seventh embodiment, the present disclosure provides an article according to any of the first through twenty-fourth or twenty-sixth embodiments, wherein the nanostructured first surface of the first layer has only protruding features.

In a twenty-eighth embodiment, the present disclosure provides an article according to any of the first, fourth, fifth, seventh through tenth, twelfth through twenty-third, or twenty-fifth through twenty-seventh embodiments, wherein b2) is present and the nanostructured first surface of the third layer comprises recessed features.

In a twenty-ninth embodiment, the present disclosure provides an article according to any of the first, fourth, fifth, seventh through tenth, twelfth through twenty-third, or twenty-fifth through twenty-eighth embodiments, wherein b2) is present and the nanostructured first surface of the third layer has only recessed features.

In a thirtieth embodiment, the present disclosure provides an article according to any of the first, fourth, fifth, seventh through tenth, twelfth through twenty-third, or twenty-fifth through twenty-eighth embodiments, wherein b2) is present and the nanostructured first surface of the third layer comprises protruding features.

In a thirty-first embodiment, the present disclosure provides an article according to any of the first, fourth, fifth, seventh through tenth, twelfth through twenty-third, twenty-fifth through twenty-seventh, or thirtieth embodiments, wherein b2) is present and the nanostructured first surface of the third layer has only protruding features.

In a thirty-second embodiment, the present disclosure provides an article according to any of the first through thirty-first embodiments, further comprising a first initiator or initiator fragment and a second initiator or initiator fragment.

In a thirty-third embodiment, the present disclosure provides an article according to any of the first through thirty-second embodiments, wherein b2) is present, wherein each of the nanostructured first surface of the first layer and the nanostructured first surface of the third layer comprises a line of nanofeatures, and wherein the line of nanofeatures of the first layer cross the line of nanofeatures of the third layer at an angle of 80 to 100 degrees.

In a thirty-fourth embodiment, the present disclosure provides an article according to any of the first, fourth, fifth, seventh through tenth, twelfth through twenty-third, or twenty-fifth through thirty-second embodiments, wherein the first layer is an inorganic layer.

In a thirty-fifth embodiment, the present disclosure provides an article according to any of the first through thirty-second embodiments, wherein the first layer comprises an oxide, a carbide, or a boride of a metal or a nonmetal, or combinations thereof.

In a thirty-sixth embodiment, the present disclosure provides an article according to the thirty-fourth embodiment or the thirty-fifth embodiment, wherein the first layer includes silica.

In a thirty-seventh embodiment, the present disclosure provides an optical information display comprising an article according to any of the first through thirty-sixth embodiments.

In a thirty-eighth embodiment, the present disclosure provides an OLED device comprising an article according to any of the first through thirty-sixth embodiments.

In a thirty-ninth embodiment, the present disclosure provides an optical element comprising the article of any of the thirty-fourth through thirty-sixth embodiments.

### EXAMPLES

Advantages and embodiments of this invention are further illustrated by the following examples, but the particular materials and amounts thereof recited in these examples, as well as other conditions and details, should not be construed to unduly limit this invention. Unless otherwise noted or readily apparent from the context, all parts, percentages, ratios, etc. in the Examples and the rest of the specification are by weight.

Materials Used in the Examples

| Description | Component | Source |
|---|---|---|
| Urethane acrylate oligomer | PHOTOMER 6210 | IGM Resins, |
| | | Charlotte, NC |
| Ethoxylated (4) bisphenol A diacrylate | SR601 | Sartomer Americas, |
| | | Exton, PA |
| Ethoxylated (10) bisphenol A diacrylate | SR602 | Sartomer Americas, |
| | | Exton, PA |
| 1,6-Hexandiol diacrylate | SR238 | Sartomer Americas, |
| | | Exton, PA |
| Trimethylolpropane triacrylate | SR351 | Sartomer Americas, |
| | | Exton, PA |
| Ethoxylated trimethylolpropane triacrylate | SR454 | Sartomer Americas, |
| | | Exton, PA |
| 2-Phenoxyethyl acrylate | ETERMER 210 | Toagosei |
| | | America Inc., |
| | | West Jefferson, OH |
| 4,4′-Methylenebis(cyclohexyl isocyanate) | HMDI | Covestro LLC, |
| | | Pittsburgh, PA |
| Polyether glycol | TERETHANE 1000 | Invista, |
| | | Wichita, KS |
| Dibutyltin dilaurate | SKU 291234 | Sigma-Aldrich |
| | | Corporation, |
| | | St. Louis, MO |
| 2-hydroxyethylacrylate | HEA | Kowa American |
| | | Corporation, |
| | | New York, |
| | | NY or Alfa Aesar, |
| | | Ward Hill, MA |
| Butylated hydroxytoluene | BHT | Oxiris |
| | | Chemicals S.A., |
| | | Barcelona, Spain |
| Methoxy hydroquinone | MEHQ | Solvay USA Inc., |
| | | Cranbury NJ |
| Antioxidant | IRGANOX 1035 | BASF, |
| | | Florham Park, NJ |
| Diphenyl(2,4,6-trimethylbenzoyl)phosphine oxide | IRGACURE TPO | BASF, |
| | | Florham Park, NJ |
| 2-Hydroxy-2-methyl-1-phenyl-propanone | DAROCUR 1173 | BASF, |
| | | Florham Park, NJ |
| 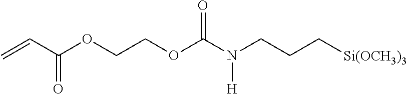 | K90 | Preparative Example 7 of U.S. Pat. No. 9,790,396 |
| 2-Propanol | 2-PROPANOL | Sigma-Aldrich |
| | | Corporation, |
| | | St. Louis, MO |
| Acrylic polymer binder thought to be a combination of | RHOPLEX 3208 | Dow |
| acrylic latex and melamine/formaldehyde curing resin | | Chemical Co., |
| with triethylamine added | | Midland, MI |
| Colloidal silica nanoparticles, nominally 16 weight | NALCO 2326 | Nalco Company |
| percent, 5 nm particle size | | (Naperville, IL) |
| 3-(methacryloyloxy)propyltrimethoxysilane | 3-(methacryloyloxy)- | Alfa Aesar |
| | propyltrimethoxysilane | (Ward Hill, MA) |
| Diethylene glycol monoethyl ether | Diethylene glycol | Alfa Aesar |
| | monoethyl ether | (Ward Hill, MA) |
| 1-Methoxy-2-propanol | 1-Methoxy-2-propanol | Aldrich Chemical |
| | | Company |
| | | (Milwaukee, WI) |
| 4-Hydroxy-TEMPO | 4-Hydroxy-TEMPO | Aldrich Chemical |
| | | Company |
| | | (Milwaukee, WI) |
| UV/Visible photoinitiator | OMNIRAD 819 | IGM Resins |
| | | (Waalwijk, |
| | | The Netherlands) |
| Octyl acrylate | OCTYL ACRYLATE | Prepared as |
| | | described in |
| | | Example 4 |
| | | of U.S. Pat. No. |
| | | 9,908,837 |
| Trimethylolpropane triacrylate | SR351 H | Sartomer |
| | | USA (Exton, PA) |
| Hexafunctional urethane acrylate | CN975 | Sartomer |
| | | USA (Exton, PA) |
| 2-Propenoic Acid, 4-benzoylphenyl ester, CAT#: 74284 | ABP | Astatech, |
| | | Bristol, PA |
| 2-Propenoic Acid, 2-(4-benzoylphenoxy) ethyl ester | AEBP | Prepared as |
| | | described in |
| | | Example B |
| | | (column 11, |
| | | lines 5-37) |
| | | of U.S. Pat. No. |
| | | 4,847,137 |
| | | (Kellen, et al.) |
| Linear triblock copolymer | KRATON G1645 | Kraton Corporation, |
| | | Houston, TX |
| Polypropylene | PP9074MED | ExxonMobil |
| | | Corporation, |
| | | Irving TX |
| PETG Copolyester | EASTAR GN071 | Eastman |
| | | Chemical Company, |
| | | Kingsport, TN |

### Color Correction on Fabricated OLED Coupon

The color-shift reduction for a blue strong-cavity OLED was tested as follows. The OLED layer structure is summarized in FIG. 3B.
Briefly, the layer structure was fabricated in the following order: a 15-nm-thick layer of indium tin oxide (ITO), a ˜100 nm hole transport layer (HTL), a 10-nm-thick electron blocking layer (EBL), a 20-nm-thick emissive layer consisting of 90% blue host material and 10% blue dopant material, a 50-nm-thick electron transport layer, a 1.5-nm-thick layer of LiF, an 8-nm-thick layer of 10% Ag and 90% Mg, and a 65-nm-thick capping layer consisting of the hole transport layer. All layers were deposited via vacuum thermal evaporation. A thin film encapsulation was then applied consisting of a 46-nm-thick layer of Al₂O₃, a 2-um-thick layer of UV-curable organic monomer (obtained under the trade designation E-200 from EM Index Company, Daejeon, Korea) and a second 46-nm-thick layer of Al₂O₃. OLED devices were fabricated with a range of HTL thicknesses; each OLED device exhibits a unique current efficiency (cd/A) and color shift. Color shift can be calculated from the CIE 1976 color coordinates (u′, v′); the magnitude of color shift is given by:

Δu′v′=SQRT((u′ᵢ−u′ₒ)²+(v′ᵢ−v′ₒ)²)) where
(u′ₒ, v′ₒ) is the color coordinate of the OLED emission at normal viewing angle and
(u′ᵢ, v′ᵢ) is the color coordinate at the i^{th} viewing angle
   The overall color shift of the device is defined as the largest color shift measured for viewing angles between 0 and 45 degrees. Color correction is defined as the reduction in the overall color-shift between the reference OLED device and the same OLED device with the film applied. A just-noticeable-difference (JND) can be defined as a vector of length 0.005 in CIE 1976 colorspace.
   Brightness and color were measured for each OLED device at normal incidence and viewing angles up to 60 degrees from normal incidence using a calibrated spectrophotometer (obtained under the trade designation SPECTRASCAN PR-655 from Photo Research, Inc., North Syracuse, N.Y.). The OLED device was attached to a rotation mount which allowed the device to be repeatedly positioned at normal incidence and viewing angles up to 60 degrees from normal incidence. Afterwards, the nanostructured film was applied to each OLED device using an index matching gel (n=1.46). Each OLED device was re-measured in an identical manner with the nanostructured film. The color correction was calculated as described above.

### Color Correction on Commercial OLED Panel

Brightness and color were measured for a Commercial OLED LGv40 Panel displaying a white screen at normal incidence and 45 degrees from normal incidence using a calibrated spectrophotometer (“SPECTRASCAN PR-655”). The LGv40 Panel was attached to a rotation mount which allowed the device to be repeatedly positioned at normal incidence and 45 degrees from normal incidence. Afterwards, the nanostructured film was applied to the LGv40 Panel using an index matching gel (n=1.46) and the device was re-measured in an identical manner with the nanostructured film. The color correction was calculated as described above.

### SEM Cross-Sections

Cross-sectioned samples were prepared using a broad beam ion mill (obtained under the trade designation GATAN ILION III Gatan, Inc., Pleasanton, Calif.) or by fracturing the sample while submersed in liquid nitrogen. The ion mill cross-sections were prepared by mounting the sample to a blade mount using silver paint and an 80 micrometer overhang about the blade edge and subjecting to an argon ion beam while under vacuum. The sample was inserted into the ion mill and cooled to −162° C. then milled at 5 KV while rotating at 1 revolution per minute (rpm). The cross-sectioned sample was imaged with a scanning electron microscope.

### Preparatory Examples

A polyurethane acrylate mixture was prepared by first adding 540 g HMDI to 1000 g TERETHANE 1000 with 0.38 g dibutyltin dilaurate as a catalyst. This isocyanate-terminated prepolymer is further reacted with 239.4 g HEA (from Kowa) in the presence of 1.4 g BHT and 0.1 g MEHQ. The reaction was considered complete when an isocyanate peak was no longer present at around 2275 cm−1 by Fourier-transform infrared spectroscopy. The resulting polyurethane acrylate was then diluted with 1021 g of SR454.
Unless noted otherwise, after all components were added the resin compositions were blended by warming to approximately 50 degrees C. and mixing for 12 hours on a roller mixer. Mixtures appeared homogeneous.
Polyurethane acrylate mixture, SR602, SR601, SR351, and ETERMER 210 were combined and mixed in weight ratios of 60/20/4/8/8 to produce Resin A.
Resin B was prepared by adding and mixing IRGACURE TPO, DAROCUR 1173 and IRGANOX 1035 in respective weight ratios of 0.35/0.1/0.2 parts per 100 parts of Resin A.
Resin C was prepared by combining and mixing 0.5 parts by weight of ABP to 99.5 parts by weight Resin B.
Resin D was prepared by combining and mixing PHOTOMER 6210, SR238, SR351 and IRGACURE TPO in weight ratios of 60/20/20/0.5.
Resin E was prepared by combining and mixing 0.5 parts by weight of AEBP to 99.5 parts by weight Resin B.
Mixture A was prepared by mixing 0.103 g DAROCUR 1173 with 9.97 g of 2-propanol.
Mixture B was prepared by mixing 0.019 g K90, 0.062 g Mixture A and 18.94 g of 2-propanol.
Film A was prepared by first preparing a multilayer film using the method described in WO 2019/032635 A1 (Johnson et al.). The resulting multilayer film had a 43 micrometer polyethylene terephthalate (PET) layer, a 6-7 micrometer linear triblock copolymer layer (“KRATON G1645”), a 6-7 micrometer layer comprising a blend of 60 parts by weight polypropylene (“PP9074MED”) and 40 parts by weight triblock copolymer (“KRATON G1645”) and a 15 micrometer copolyester layer (“EASTAR GN071”). Resin C was die coated from a heated storage container, through a heated hose and a heated die all set to 65.5° C. onto the copolyester surface of the multilayer film. The coated side of the film was pressed against a nanostructured nickel surface attached to a steel roller controlled at 71° C. using a rubber-covered roller at a speed of 7.6 meters per minute (m/min). The coating thickness of Resin C on the film was sufficient to fully wet the nanostructured nickel surface and form a rolling bead of resin as the coated film was pressed against the nanostructured nickel surface. The resin-coated film was exposed to radiation from a Phoseon UV LED curing system (obtained under the trade designation “FIREJET FJ 300X20AC405-12W”, from Phoseon Technologies, Hillsboro, Oreg.) operating at 100% power while in contact with the nanostructured nickel surface. Nanostructured Film A was peeled from the nanostructured nickel surface. An SEM image of the nanostructured surface of Film A is shown in FIG. 8.
Film B was prepared by the same procedure as Film A except a smooth chrome surface was used in place of the nanostructured nickel surface, the copolyester layer thickness was 5 micrometers, and the Phoseon UV LED curing system was operated at 75% power.
Film C was prepared by pressing the nanostructured surface of Film A to the Resin C coated surface of Film B between a smooth chrome roller and a rubber covered roller at a speed of 6.1 m/min. The Film A side of the construction was exposed to energy from a Fusion UV lamp system (obtained under the trade designation “F600” from Fusion UV Systems, Gaithersburg, Md.) fitted with a D bulb operating at 236 Watts per centimeter (W/cm) while the construction was still in contact with the smooth chrome roller. The Film B side of the construction was exposed to energy from a Fusion UV lamp system (“F600”) fitted with a D bulb operating at 141 W/cm after removing the construction from the smooth chrome roller.
Film D was prepared by the same procedures as Film A using a different nanostructured nickel surface. An SEM image of the nanostructured surface of Film D is shown in FIG. 9B.

### Film E

Film E was prepared by die coating Resin E from a heated storage container, through a heated hose and heated die, all set to 65.5° C., onto a 125 micrometer thick polycarbonate film with a gloss surface finish on both sides (obtained under the trade designation “LEXAN” from Tekra, Inc., New Berlin, Wis.). The coated side of the film was pressed against nanostructured nickel mold attached to a steel roller controlled at 65° C. using a rubber covered roller at a speed of 7.6 m/min. The coating thickness of Resin E on the film was sufficient to fully wet the nickel surface and form a rolling bead of resin as the coated film was pressed against the nanostructured nickel surface. The film was exposed to radiation from two Fusion UV lamp systems (“F600”) fitted with D bulbs both operating at 142 and 236 W/cm, respectively, while in contact with the nanostructured mold surface. The resulting Film E was peeled from the nanostructured mold surface. An SEM image of the nanostructured surface of Film E is shown in FIG. 10B.

### Film F

Film F was prepared using the following procedure. First, a nanostructured film was prepared using the procedure used to produce Film A with the following changes: a nanostructured nickel surface having linear nanostructured features was used, Resin D was used in place of Resin C, Resin D was coated at ambient conditions, the steel roller was controlled at 65° C., and the resin-coated film was exposed to radiation from two Fusion UV lamp systems (“F600”) fitted with D bulbs both operating at 142 W/cm. A nanostructured film mold was made by depositing a thin coating on the resulting nanostructured film using plasma enhanced chemical vapor deposition (PECVD). PECVD was performed in a home-built parallel plate capacitively coupled plasma reactor. The chamber has a central cylindrical powered electrode with a surface area of 18.3 ft2. After placing the nanostructured film on the powered electrode, the reactor chamber was pumped down to a base pressure of less than 1.3 Pa (2 mTorr). Oxygen was introduced into the chamber at a flow rate of 1000 standard cubic centimeters per minute (SCCM). Treatment was carried out by coupling RF power into the reactor at a frequency of 13.56 MHz and an applied power of 2000 watts. Treatment time was controlled by moving the nanostructured film through the reaction zone at rate of 30 ft/min. A second step resulting in a deposited thin film on the nanostructured surface was accomplished by stopping the flow of oxygen and evaporating and transporting HMDSO (hexamethyldisiloxane) into the system to sustain an operating pressure of approximately 9 mTorr. Treatment was carried out using a plasma enhanced CVD method by coupling RF power into the reactor at a frequency of 13.56 MHz and an applied power of 1000 watts. Treatment time was controlled by moving the nanostructured film back through the reaction zone at rate of 30 ft/min. Following the treatment, the RF power and the gas supply were stopped and the chamber was returned to atmospheric pressure. Additional information regarding materials and processes for applying cylindrical PECVD and further details around the reactor used can be found in U.S. Pat. No. 8,460,568 B2 (Moses et al.).
The nanostructured film mold was then adhered to a 1.6 mm thick aluminum plate with the nanostructured side up and a piece of 75 micrometer thick biaxially-oriented polyethylene terephthalate (PET) film (prepared in-house) primed with an acrylic polymer (“RHOPLEX 3208” from Dow, Midland, Mich.) adhesion promoter was placed over the nanostructured film mold with the primed side down and adhered along its leading edge using tape to the nanostructured film mold. A bead of Resin B was placed along the leading edge of the construction between the PET and the nanostructured film mold contacting the primed side of the PET and the nanostructured side of the nanostructured film mold. The aluminum plate, nanostructured film mold, resin and PET film construction was passed through a bench top laminator (“HL-100” from ChemInstruments, Fairfield, Ohio) at a speed setting of “2” and a pressure of 16 psi (110 kps). The laminated construction was then exposed to radiation from a Phoseon UV LED curing system (“FIREJET FJ 300X20AC405-12W” obtained from Phoseon Technology, Hillsboro, Oreg.) operating at 50% power at a speed of 7.6 m/min. Film F was then peeled from the nanostructured film mold.

### Film G

Film G was prepared using the following procedure. First, Resin D was die coated at room temperature onto a 75 micron thick biaxially-oriented polyethylene terephthalate (PET) film (prepared in-house) primed with an acrylic polymer (“RHOPLEX 3208”) adhesion promoter. The coated film was pressed against a nanostructured nickel surface attached to a steel roller controlled at 49° C. using a rubber covered roller at a speed of 9.1 m/min. The coating thickness of Resin D on the film was sufficient to fully wet the nickel surface and form a rolling bead of resin as the coated film was pressed against the nanostructured nickel surface. The film was exposed to radiation from two UV lamp systems (obtained under the trade designation “F600” from Fusion UV Systems, Gaithersburg, Md.) both fitted with D bulbs and dichroic reflectors and operating at 236 W/cm while in contact with the nanostructured nickel surface. Nanostructured Film G was peeled from the nickel surface.

### Film H

Film H was prepared using the following procedure. First, Resin D was die coated at room temperature onto a 125 micrometer thick polycarbonate film with a gloss surface finish on both sides (obtained under the trade designation “LEXAN” from Tekra, Inc., New Berlin, Wis.). The coated side of the film was pressed against a nanostructured mold attached to a steel roller controlled at 60° C. using a rubber covered roller at a speed of 15.2 m/min. The coating thickness of Resin D on the film was sufficient to fully wet the nickel surface and form a rolling bead of resin as the coated film was pressed against the nanostructured nickel surface. The film was exposed to radiation from two UV lamp systems (“F600” from Fusion UV Systems) fitted with D bulbs and dichroic reflectors both operating at 142 W/cm, while in contact with the nanostructured mold surface. The resulting nanostructured film was peeled from the nanostructured mold surface and then the nanostructured surface of the film was exposed to radiation from a UV lamp system (“F600” from Fusion UV Systems) fitted with a D bulb and dichroic reflector operating at 142 W/cm.

### Film I

Film I was prepared using the following procedure. A silicon containing release layer according to methods described in U.S. Pat. No. 6,696,157 (David et al.) and U.S. Pat. No. 8,664,323 (Iyer et al.) and U.S. Patent Publication No. 2013/0229378 (Iyer et al.) was applied to nanostructured Film H in a parallel plate capacitively coupled plasma reactor to produce nanostructured Film I. The chamber has a central cylindrical powered electrode with a surface area of 1.7 m² (18.3 ft²). After placing the nanostructured film on the powered electrode, the reactor chamber was pumped down to a base pressure of less than 1.3 Pa (2 mTorr). O₂ gas was flowed into the chamber at a rate of 1000 SCCM. Treatment was carried out using a plasma enhanced CVD method by coupling RF power into the reactor at a frequency of 13.56 MHz and an applied power of 2000 watts. Treatment time was controlled by moving the nanostructured film through the reaction zone at rate of 9.1 m/min (30 ft/min) resulting in an approximate exposure time of 10 seconds. After completing the deposition, RF power was turned off and gasses were evacuated from the reactor. Following the first treatment, a second plasma treatment was carried out in the same reactor without returning the chamber to atmospheric pressure. HMDSO gas was flowed into the chamber at approximately 1750 SCCM to achieve a pressure of 9 mTorr. 13.56 MHz RF power was subsequently coupled into the reactor with an applied power of 1000 W. The nanostructured film was then carried through the reaction zone at a rate of 9.1 m/min (30 ft/min) resulting in an approximate exposure time of 10 seconds. At the end of this treatment time, the RF power and the gas supply were stopped, and the chamber was returned to atmospheric pressure.

### Film J

Multilayer Film J was prepared using the method described in PCT Publ. No. WO 2019/032635 A1 (Johnson, et al.). The resulting multilayer film had a 43 micron polyethylene terephthalate (PET) layer, a 6 to 7 micron linear B-E-S triblock copolymer layer (“KRATON G1645”), a 6 to 7 micron layer comprising a blend of 70 parts by weight polypropylene random copolymer (“PP9074MED”) and 30 parts by weight B-E-S triblock copolymer (“KRATON G1645”) and a 10 micron PETG copolyester layer (“EASTAR GN071”).

### Film K

Nanostructured Film K was prepared by first attaching the leading edge of nanostructured Film I onto a 1.6 mm thick aluminum plate with the nanostructured surface away from the aluminum plate with tape. A piece of multilayer Film J was place over nanostructured Film I with the PETG surface adjacent to the nanostructured surface of nanostructured Film I and attached to the aluminum plate with tape. The films and plate were placed into a 60° C. oven for 1 minute. Resin B was heated in a 60° C. oven and a bead of the heated Resin B was placed between the two films. The Film J/Resin B/Film I/aluminum plate construction was passed through a bench top laminator (obtained under the trade designation “Model HL-100” from Cheminstruments, Inc. Fairfield Ohio) at a speed setting of “1”, top and bottom roller temperatures set to 60° C., and a pressure setting of 15 psi (103 kpa). The Film J/Resin B/Film I/aluminum plate construction was exposed to radiation from a UV LED curing system (obtained under the trade designation “FIREJET FJ 300X20AC405-12W”, from Phoseon Technologies, Hillsboro, Oreg.) operating at 25% power at a speed of 15.2 m/min twice. Nanostructured Film K was removed from the nanostructured Film I.

### Structured Sample A

Structured Sample A was prepared using the following procedure. A concentrated sol of surface-modified silica nanoparticles (Nalco 2326 modified with 3-(methacryloyloxy)propyltrimethoxysilane) in diethylene glycol monoethyl ether was prepared as described in Example 1 of U.S. Patent Application Publication No. US 2019/0185328 (Humpal et al.). The resulting sol contained 45.60 weight percent oxide. To prepare the casting sol, a portion of the concentrated sol (200.14 grams) was charged to a 500-mL bottle and combined with diethylene glycol monoethyl ether (1.48 grams), HEA (2.83 grams, from Alfa Aesar), octyl acrylate (5.68 grams), trimethylolpropane triacrylate (SR351 H) (50.00 grams), and a hexafunctional urethane acrylate (CN975) (24.95 grams). OMNIRAD 819 (6.84 grams) was dissolved in diethylene glycol monoethyl ether (174.14 grams) and added to the bottle. The casting sol was passed through a 1-micron filter. The casting sol contained 19.58 weight percent oxide and 56.41 weight percent solvent.
The casting sol was charged to an acrylic mold cavity (dimensions: 30 mm×30 mm×3 mm). The structured side of nanostructured Film G formed one face of the mold cavity. The walls of the mold cavity were treated with a release coating. Once the cavity was filled, the casting sol was cured (polymerized) for 30 seconds using a LED array positioned 40 mm away from the surface of the mold. The diodes, with a wavelength of 450 nm, were spaced 8 mm apart in a 10×10 array. The resulting shaped gel replicated the features of the structured film tool, felt dry, and was robust to handling when removed from the mold. The shaped gel was then dried using supercritical CO₂ extraction in a manner similar to that described the Examples section of U.S. Patent Application Publication No. US 2019/0185328 (Humpal et al.). The shaped aerogel was crack-free after drying. This shaped aerogel was placed on 3-mm diameter quartz rod on a 1-mm thick alumina plate and heated in air to remove organic components and densify, according to the heating schedules described in the Examples section of U.S. Patent Application Publication No. US 2019/0185328 (Humpal et al.) except for minor changes to the times and temperatures. The resulting Structured Sample A was crack-free, transparent, and replicated the mold features precisely.

### Structured Sample B

Structured Sample B was prepared using the following procedure. Structured Sample A was placed in an ozone cleaner (obtained under the trade designation UVO Cleaner Model 144AX from Jelight Company, Irvine Calif.). A drop of Mixture B was then placed onto the structured surface of Structured Sample A using a disposable pipet. Mixture B was then spread over the structured surface using a #7 wire wound coating rod (obtained under trade designation RDS07 from R.D. Specialties, Inc., Webster N.Y.). The coated Structured Sample A was allowed to dry at room temperature and then placed into a 75° C. oven for 60 minutes resulting in Structured Sample B. A scanning electron microscope image at 10,000× of the structured surface of a second sample prepared using the same procedure as Structured Sample B is shown in FIG. 12A.

### Example 1

Example 1 (shown schematically in FIG. 4A) was prepared by laminating the nanostructured surfaces of two pieces of Film A together by positioning the films, taping the leading edge of films onto a 1.6 mm thick aluminum plate, placing the top film over the top roll of the laminator so the two films contact at the nip point of the laminator. The films were laminated with a bench top laminator (obtained under the trade designation “Model HL-100” from ChemInstruments, Inc. Fairfield Ohio) at a speed setting of 2 and a pressure of 16 psi (110 kilopascals). The laminated construction was passed under the UV light from a Fusion UV lamp system (“F600”) fitted with an H bulb operating at 236 W/cm. The nanostructured layer of example 1 was ion mill cross-sectioned and imaged (FIG. 4B). The color correction of Example 1 was measured and is reported in Table 1 below.

TABLE 1
Color correction summary.

| | | Initial | Blue Color- | | Color | Color |
|---|---|---|---|---|---|---|
| | Encapsulation | Blue Color- | Shift with | Color | Correction | Correction |
| Example | Description | Shift | Film | Correction | (JND) | Testbed |
| Example 1 | Dual Layer | 0.028 | 0.014 | 0.014 | 2.8 | Fabricated OLED Coupon |
| Example 1 | Dual Layer | 0.044 | 0.023 | 0.021 | 4.2 | Fabricated OLED Coupon |
| Example 1 | Dual Layer | 0.061 | 0.047 | 0.014 | 2.8 | Fabricated OLED Coupon |
| Example 2 | Single Layer and | 0.021 | 0.014 | 0.007 | 1.4 | Commercial Panel (LGv40) |
| | Dual Layer | | | | | |
| Example 3 | Two Dual Layers | 0.021 | 0.012 | 0.009 | 1.8 | Commercial Panel (LGv40) |
| Example 4 | Two Single Layers | 0.021 | 0.012 | 0.009 | 1.8 | Commercial Panel (LGv40) |
| Comp Example 1 | Single Layer | 0.020 | 0.011 | 0.009 | 1.8 | Fabricated OLED Coupon |
| Comp Example 1 | Single Layer | 0.031 | 0.025 | 0.006 | 1.2 | Fabricated OLED Coupon |
| Comp Example 1 | Single Layer | 0.046 | 0.039 | 0.007 | 1.4 | Fabricated OLED Coupon |
| Comp Example 2 | Solid Backfill | 0.018 | 0.012 | 0.006 | 1.2 | Fabricated OLED Coupon |
| Comp Example 2 | Solid Backfill | 0.029 | 0.024 | 0.005 | 1 | Fabricated OLED Coupon |
| Comp Example 2 | Solid Backfill | 0.046 | 0.041 | 0.005 | 1 | Fabricated OLED Coupon |

### Example 2

Example 2 (shown schematically in FIG. 5A) was prepared by first preparing the dual layer construction of Example 1. Film B was laminated to the Example 1 construction by taping the leading edge of the films onto a 1.6 mm thick aluminum plate, placing the top film over the top roll of the laminator so the films contact at the nip point of the laminator. The films were laminated placing a bead of resin D along the leading edge of the lower film and laminating the films with a bench top laminator (“HL-100) at a speed setting of 2 and a pressure of 16 psi (110 kilopascals). The laminated construction was passed under the UV light from a Fusion UV lamp system (“F600”) fitted with a D bulb operating at 236 W/cm. Example 2 was ion mill cross-sectioned and imaged with SEM (FIGS. 5B-5D). The color correction of Example 2 was measured and is reported in Table 1.

### Example 3

Example 3 (shown schematically in FIG. 6A) was prepared by first preparing two dual layer constructions of Example 1. The two Example 1 constructions were laminated by taping the leading edge of the constructions onto a 1.6 mm thick aluminum plate, placing the top film over the top roll of the laminator so the films contact at the nip point of the laminator. The films were laminated placing a bead of resin D along the leading edge of the lower film and laminating with a bench top laminator (“HL-100) at a speed setting of 2 and a pressure of 16 psi (110 kilopascals). The laminated construction was passed under the UV light from a Fusion UV lamp system (“F600”) fitted with a D bulb operating at 236 W/cm. Example 3 was ion mill cross-sectioned and imaged with SEM (FIGS. 6B-6D). The color correction of Example 3 was measured and is reported in Table 1.

### Example 4

Example 4 (shown schematically in FIG. 7A) was prepared by laminating two pieces of Film C using the following procedure. Two pieces of Film C were laminated by taping the leading edge of films onto a 1.6 mm thick aluminum plate, placing the top film over the top roll of the laminator so the films contact at the nip point of the laminator. The films were laminated placing a bead of resin D along the leading edge of the lower film and laminating with a bench top laminator (“HL-100) at a speed setting of 2 and a pressure of 16 psi (110 kilopascals). The laminated construction was passed under the UV light from a Fusion UV lamp system (“F600”) fitted with a D bulb operating at 236 W/cm. Example 4 was ion mill cross-sectioned and imaged with SEM (FIGS. 7B-7D). The color correction of Example 4 was measured and reported in Table 1.

### Example 5

Example 5 was prepared by laminating the nanostructured surface of Film A to the nanostructured surface of Film E using the following procedure. Film A was placed nanostructured side up on a 1.6 mm thick aluminum plate. The nanostructured surface of Film E was placed down over Film A. The two pieces of film were attached to the aluminum plate by taping their leading edges to the aluminum plate. The construction was placed into a bench top laminator (“HL-100”) with the leading edge just past the nip point and the laminator nip was closed. The films were laminated at a speed setting of 1, a pressure of 12 psi (110 kilopascals) and the top and bottom roll temperatures set to 60° C. The laminated construction was passed under the UV light from a Fusion UV lamp system (“F600”) fitted with a D bulb operating at 236 W/cm at a speed of 7.6 m/min to produce Example 5.

### Example 6

Example 6 (shown schematically in FIG. 11A) was prepared as follows. A piece of Film F was placed nanostructured side up on a 1.6 mm thick aluminum plate. A second piece of Film F was rotated 90 degrees and placed nanostructured side down over the first piece of Film F so the linear direction of the nanostructures of the two pieces were approximately orthogonal. The two pieces of film were attached to the aluminum plate and laminated and exposed to radiation using the same procedure as Example 5 using a speed setting of 2. The resulting Example 6 was cross-sectioned by fracturing in liquid nitrogen and the nanostructured area was imaged with SEM (FIG. 11B).

### Example 7

Example 7 was prepared by laminating the nanostructured side of nanostructured Film K to the nanostructured surface of Structured Sample B with a hand roller. The nanostructured Film K side of the laminated construction was exposed to radiation from a UV lamp system (“F600” from Fusion UV Systems) fitted with a D bulb and a dichroic reflector operating at 236 W/cm at a speed of 15.2 m/min twice. The PET, triblock copolymer layer and polypropylene layers were removed from the construction. The resulting Example 7 was cross-sectioned by applying a piece of tape to the unstructured side of Structured Sample B, grasping Example 7 with two pair of glass pliers and flexing Example 7. The resulting cross-section was imaged with a scanning electron microscope and the resulting micrograph at 20,000× magnification is shown in FIG. 12B.

### Comparative Example 1

Film C was prepared as described above. The color correction was measured and reported in Table 1.

### Comparative Example 2

Film A was prepared and backfilled using the backfill formulation described in Example 4 of US Patent Application US2019/0338142 A1 (Hartmann-Thompson et al.) except the nanoparticle solution was 68% and the resin mixture was 32% of the backfill formulation. The color correction of the resulting Comparative Example 2 was measured and reported in Table 1.

All of the patents and patent applications mentioned above are hereby expressly incorporated by reference. In the event that any inconsistency exists between the disclosure of the present application and the disclosure(s) of any document incorporated herein by reference, the disclosure of the present application shall govern. The embodiments described above are illustrative of the present invention and other constructions are also possible. Accordingly, the present invention should not be deemed limited to the embodiments described in detail above and shown in the accompanying drawings, but instead only by a fair scope of the claims that follow along with their equivalents.

1. An article comprising:
a) a first layer comprising a nanostructured first surface comprising nanofeatures and an opposing second surface, wherein the nanostructured first surface comprises recessed features, or protruding features formed of a single composition, or both recessed and protruding features; and either:
b1) a second layer comprising a first major surface and an opposing second major surface, the first major surface attached to a portion of the nanofeatures of the first layer, wherein the nanostructured first surface of the first layer and the first major surface of the second layer together define at least one first void; or
b2) a third layer comprising a nanostructured first surface comprising nanofeatures and an opposing second surface, wherein a portion of the nanofeatures of the third layer are attached to a portion of the nanofeatures of the first layer, and wherein the nanostructured first surface of the third layer and the nanostructured first surface of the first layer together define at least one second void;
wherein either 1) the first layer comprises an inorganic material that comprises a coupling agent bonded to the nanostructured first surface of the first layer or 2) the first layer comprises an organic material and comprises crosslinks between the first layer and whichever of b1) or b2) that is present;
with the proviso that when b1) is present, the article further comprises:
c) a fourth layer comprising a nanostructured first surface comprising nanofeatures and an opposing second surface,
wherein either the second surface of the fourth layer or the nanostructured first surface of the fourth layer is adjacent either to the second major surface of the second layer or to the second surface of the first layer.

2. The article of claim 1, wherein b1) is present.

3. The article of claim 1, wherein b1) is present and the article further comprises:
d) a fifth layer comprising a first major surface and an opposing second major surface, wherein the first major surface is attached to a portion of the nanofeatures of the fourth layer, wherein the nanostructured first surface of the fourth layer and the first major surface of the fifth layer together define at least one third void.

4. The article of claim 1, wherein b2) is present and the article further comprises:
e) a sixth layer comprising a nanostructured first surface comprising nanofeatures and an opposing second surface; and
f) a seventh layer comprising a first major surface and an opposing second major surface, wherein the first major surface is attached to a portion of the nanofeatures of the sixth layer, and wherein the nanostructured first surface of the sixth layer and the first major surface of the seventh layer together define at least one fourth void,
wherein either the second surface of the sixth layer or the second major surface of the seventh layer is adjacent either to the second major surface of the second layer or to the second surface of the first layer.

5. The article of claim 1, wherein b2) is present and the article further comprises:
g) an eighth layer comprising a nanostructured first surface comprising nanofeatures and an opposing second surface; and
h) a ninth layer comprising a nanostructured first surface comprising nanofeatures and an opposing second surface, wherein a portion of the nanofeatures of the ninth layer are attached to a portion of the nanofeatures of the eighth layer, and wherein the nanostructured first surface of the ninth layer and the nanostructured first surface of the eighth layer together define at least one fifth void,
wherein either the second surface of the eighth layer or the second surface of the ninth layer is adjacent to either the second surface of the third layer or the second surface of the first layer.

6. The article of claim 1, wherein b1) is present and the article further comprises:
i) a tenth layer comprising a nanostructured first surface comprising nanofeatures and an opposing second surface; and
j) an eleventh layer comprising a nanostructured first surface comprising nanofeatures and an opposing second surface, wherein a portion of the nanofeatures of the eleventh layer are attached to a portion of the nanofeatures of the tenth layer, and wherein the nanostructured first surface of the eleventh layer and the nanostructured first surface of the tenth layer together define at least one sixth void,
wherein either the second surface of the tenth layer or the second surface of the eleventh layer is adjacent to either the second major surface of the second layer or the second surface of the first layer.

7. The article of claim 1, further comprising a twelfth layer disposed adjacent to either the second major surface of the second layer or the second surface of the first layer.

8. The article of claim 7, wherein the twelfth layer is a low bi-refringent layer.

9. The article of claim 1, further comprising a thirteenth layer disposed adjacent to either the second major surface of the second layer or the second surface of the first layer.

10. The article of claim 1, wherein the second layer is substantially planar.

11. The article of claim 1, wherein the first layer comprises a polymeric material.

12. The article of claim 1, wherein the first layer and either the second layer or the third layer comprise the same material.

13. The article of claim 1, wherein at least one of the first layer, the second layer, or the third layer comprises a crosslinked material or a crosslinkable material.

14. The article of claim 1, wherein at least one of the first layer, the second layer, or the third layer comprises an acrylic polymer or copolymer.

15. The article of claim 1, wherein at least one of the first layer, the sixth layer, the eighth layer, the ninth layer, the tenth layer, or the eleventh layer comprises nanofeatures having at least one non-linear surface in at least one direction.

16. The article of claim 1, wherein b2) is present,
wherein each of the nanostructured first surface of the first layer and the nanostructured first surface of the third layer comprises a line of nanofeatures, and wherein the line of nanofeatures of the first layer cross the line of nanofeatures of the third layer at an angle of 80 to 100 degrees.

17. An optical information display comprising the article of claim 1.

18. An OLED device comprising the article of claim 1.
